(19) United States
(12) Patent Application Publication
(10) Pub. No.: US 2024/0304648 A1
(43) Pub. Date: Sep. 12, 2024

(54) SOLID-STATE IMAGING DEVICE AND MANUFACTURING METHOD FOR SOLID-STATE IMAGING DEVICE

(71) Applicant: SONY SEMICONDUCTOR SOLUTIONS CORPORATION, KANAGAWA (JP)

(72) Inventor: NAOKI YAMASHITA, KUMAMOTO (JP)

(21) Appl. No.: 18/546,631

(22) PCT Filed: Jan. 25, 2022
(86) PCT No.: PCT/JP2022/002687

§ 371 Date: Aug. 16, 2023

(30) Foreign Application Priority Data
Feb. 24, 2021 (JP) 2021-027869

(51) Int. Cl. H01L 27/146; H01L 23/00

(52) U.S. Cl. CPC H01L 27/14636; H01L 24/03; H01L 24/05; H01L 24/94; H01L 27/14687; H01L 27/14634; H01L 2224/03462; H01L 2224/03464; H01L 2224/05082; H01L 2224/05147; H01L 2224/05166; H01L 2224/05541; H01L 2224/05561; H01L 2224/05644; H01L 2224/05647; H01L 2224/05655; H01L 2224/94

(57) ABSTRACT

A device size is further reduced. A solid-state imaging device includes: a substrate including an imaging element configured to generate an electric signal obtained by photoelectrically converting light incident on a first surface; and a conductor disposed on at least one of a second surface opposite to the first surface of the substrate or a side surface continuous with the second surface of the substrate and electrically connected to the imaging element.

### TECHNICAL FIELD

Embodiments of the present disclosure relate to a solid-state imaging device and a manufacturing method for the solid-state imaging device.

### BACKGROUND ART

The size of a solid-state imaging device such as a complementary metal oxide semiconductor (CMOS) image sensor has been reduced (for example, refer to Patent Document 1).

### CITATION LIST

### Patent Document

Patent Document 1: Japanese Patent Application Laid-Open No. 2017-175047

### SUMMARY OF THE INVENTION

### Problems to be Solved by the Invention

However, there is a demand for further reducing the package size of the solid-state imaging device.

Therefore, the present disclosure provides a solid-state imaging device of which the device size can be reduced and a manufacturing method for the solid-state imaging device.

### Solutions to Problems

In order to solve the above-described problem, according to an aspect of the present disclosure, there is provided a solid-state imaging device including:
a substrate including an imaging element configured to generate an electric signal obtained by photoelectrically converting light incident on a first surface; and
a conductor disposed on at least one of a second surface opposite to the first surface of the substrate or a side surface continuous with the second surface of the substrate and electrically connected to the imaging element.

The conductor may be in surface contact with at least one of the second surface or the side surface.

On at least one of the second surface or the side surface, an arrangement place of the conductor may be flush with other places.

A contact member extending in a depth direction of the substrate and electrically connected to the imaging element may be further provided, and the conductor may be electrically connected to the contact member.

The substrate may include a signal output unit configured to transmit and receive a signal to and from the imaging element, and the signal output unit may be connected to one end of the contact member.

The substrate may include:
a first substrate on which a photoelectric conversion unit in the imaging element is disposed; and
a second substrate that is stacked on the first substrate and performs signal processing on an electric signal photoelectrically converted by the photoelectric conversion unit, and
the contact member may extend in the depth direction of the first substrate and second substrate.

The substrate may include:
a first substrate on which a photoelectric conversion unit in the imaging element is disposed; and
a second substrate that is stacked on the first substrate and performs signal processing on an electric signal photoelectrically converted by the photoelectric conversion unit,
the first substrate may include a signal output unit configured to transmit and receive a signal to and from the imaging element,
the first substrate may include a conductive connection portion electrically connected to the signal output unit and extending to a side surface of the first substrate, and
the conductor may be connected to the conductive connection portion and disposed on the side surface of the first substrate.

The substrate may include:
a first substrate on which a photoelectric conversion unit in the imaging element is disposed; and
a second substrate that is stacked on the first substrate and performs signal processing on an electric signal photoelectrically converted by the photoelectric conversion unit,
the second substrate may include a signal output unit configured to transmit and receive a signal to and from the imaging element,
the second substrate may include a conductive connection portion electrically connected to the signal output unit and extending to a side surface of the second substrate, and
the conductor may be connected to the conductive connection portion and disposed on the side surface of the second substrate.

The conductor may be disposed on side surfaces of the first substrate and second substrate and on the second surface of the second substrate.

The conductor may be disposed only on the second surface or only on the side surface.

The conductor may be disposed continuously from the second surface to the side surface.

The conductor disposed on the second surface and the conductor disposed on the side surface may be provided separated from each other.

A coupling portion that is disposed on at least one of the second surface or the side surface and couples a plurality of the conductors may be further provided, and a plurality of the conductors coupled by the coupling portion may share a signal output unit electrically connected to the conductors and configured to transmit and receive a signal to and from the imaging element.

A coupling portion that is disposed on at least one of the second surface or the side surface and couples a plurality of the conductors may be further provided, and a plurality of the conductors coupled by the coupling portion may be shared through a plurality of signal output units electrically connected to the conductors and configured to transmit and receive a signal to and from the imaging element.

The conductor may include a single-layered conductive layer.

The conductor may include a multi-layered conductive layer.

According to another aspect of the present disclosure, there is provided a manufacturing method for a solid-state imaging device, the method including:
forming, on a first surface of a substrate, an imaging element configured to generate an electric signal obtained by photoelectrically converting light incident on the first surface; and
forming a conductor disposed on at least one of a second surface opposite to the first surface of the substrate or a side surface continuous with the second surface of the substrate and electrically connected to the imaging element.

There may be further provided:
forming the imaging element on the first surface of the substrate;
forming a hole extending in a depth direction of the substrate from the second surface side of the substrate so as to expose a signal output unit configured to transmit and receive a signal to and from the imaging element; and
forming a contact member extending in the depth direction of the substrate and the conductor electrically connected to the contact member by forming a metal layer from the second surface side of the substrate so as to fill the hole.

There may be further provided:
forming the imaging element on the first surface of the substrate before dividing the substrate into individual pieces;
forming a conductive connection portion electrically connected to a signal output unit configured to transmit and receive a signal to and from the imaging element and extending to a first region including a part of a dividing region for dividing the substrate into individual pieces;
forming, in the first region, a hole extending in a depth direction of the substrate from the second surface side of the substrate such that the conductive connection portion is exposed;
forming a metal layer from the second surface side of the substrate so as to fill the hole to form the conductor electrically connected to the conductive connection portion; and
dividing the substrate into individual pieces along the dividing region.

There may be further provided:
forming the imaging element on the first surface of the substrate before dividing the substrate into individual pieces;
forming a sacrificial layer extending to a first region including a part of a dividing region for dividing the substrate into individual pieces;
forming, in the first region, a hole extending in a depth direction of the substrate from the second surface side of the substrate such that the sacrificial layer is exposed; removing the sacrificial layer;
forming, in a region where the sacrificial layer is
removed, a conductive connection portion electrically connected to a signal output unit configured to transmit and receive a signal to and from the imaging element and forming a metal layer from the second surface side of the substrate so as to fill the hole to form the conductor electrically connected to the conductive connection portion; and
dividing the substrate into individual pieces along the dividing region.

### BRIEF DESCRIPTION OF DRAWINGS

FIG. 1 is a diagram illustrating a circuit configuration example of a substrate of a solid-state imaging device.

FIG. 2 is a diagram illustrating an equivalent circuit of a pixel.

FIG. 3 is a side view illustrating an example of an external configuration of a solid-state imaging device according to a first embodiment.

FIG. 4 is a plan view illustrating an example of an external configuration of a solid-state imaging device according to the first embodiment.

FIG. 5 is a cross-sectional view illustrating an example of a configuration of a solid-state imaging device according to the first embodiment.

FIG. 6 is an enlarged plan view in which a conductor and a periphery thereof in a broken-line frame in FIG. 4 are enlarged.

FIG. 7 is an enlarged cross-sectional view illustrating a configuration of a solid-state imaging device in a cross section taken along line A-A in FIG. 6.

FIG. 8 is an enlarged cross-sectional view illustrating a configuration of a solid-state imaging device in a cross section taken along line B-B in FIG. 6.

FIG. 9A is a diagram illustrating a configuration example of a substrate.

FIG. 9B is a diagram illustrating a configuration example of a substrate.

FIG. 10 is a cross-sectional view illustrating an example of a configuration of a solid-state imaging device according to the first embodiment.

FIG. 11 is a perspective view illustrating an example of a configuration of a solid-state imaging device according to the first embodiment.

FIG. 12 is an external view illustrating an example of connection between a solid-state imaging device and a mount substrate according to the first embodiment.

FIG. 13 is a view illustrating an example of a configuration of a solid-state imaging device according to a comparative example.

FIG. 14A is a cross-sectional view illustrating an example of a manufacturing method for a solid-state imaging device according to the first embodiment.

FIG. 14B is a cross-sectional view illustrating an example of a manufacturing method for a solid-state imaging device, subsequent to FIG. 14A.

FIG. 14C is a cross-sectional view illustrating an example of a manufacturing method for a solid-state imaging device, subsequent to FIG. 14B.

FIG. 14D is a cross-sectional view illustrating an example of a manufacturing method for a solid-state imaging device, subsequent to FIG. 14C.

FIG. 14E is a cross-sectional view illustrating an example of a manufacturing method for a solid-state imaging device, subsequent to FIG. 14D.

FIG. 14F is a cross-sectional view illustrating an example of a manufacturing method for a solid-state imaging device, subsequent to FIG. 14E.

FIG. 14G is a cross-sectional view illustrating an example of a manufacturing method for a solid-state imaging device, subsequent to FIG. 14F.

FIG. 14H is a cross-sectional view illustrating an example of a manufacturing method for a solid-state imaging device, subsequent to FIG. 14G.

FIG. 15 is a cross-sectional view illustrating a first modification example of a configuration of a solid-state imaging device according to the first embodiment.

FIG. 16 is an enlarged cross-sectional view illustrating an example of a configuration of a solid-state imaging device according to a second embodiment.

FIG. 17 is a cross-sectional view illustrating an example of a configuration of a solid-state imaging device according to the second embodiment.

FIG. 18 is a cross-sectional view illustrating an example of a manufacturing method for a solid-state imaging device according to the second embodiment.

FIG. 19 is an enlarged cross-sectional view illustrating a modification example of a configuration of a solid-state imaging device according to the second embodiment.

FIG. 20 is an enlarged cross-sectional view illustrating an example of a configuration of a solid-state imaging device according to a third embodiment.

FIG. 21 is a cross-sectional view illustrating an example of a configuration of a solid-state imaging device 1 according to the third embodiment.

FIG. 22A is a cross-sectional view illustrating an example of a manufacturing method for a solid-state imaging device according to the third embodiment.

FIG. 22B is a cross-sectional view illustrating an example of a manufacturing method for a solid-state imaging device, subsequent to FIG. 22A.

FIG. 22C is a cross-sectional view illustrating an example of a manufacturing method for a solid-state imaging device, subsequent to FIG. 22B.

FIG. 22D is a cross-sectional view illustrating an example of a manufacturing method for a solid-state imaging device, subsequent to FIG. 22C.

FIG. 23 is an enlarged cross-sectional view illustrating a modification example of a configuration of a solid-state imaging device according to the third embodiment.

FIG. 24 is an enlarged cross-sectional view illustrating an example of a configuration of a solid-state imaging device according to a fourth embodiment.

FIG. 25 is an enlarged cross-sectional view illustrating a modification example of a configuration of a solid-state imaging device according to the fourth embodiment.

FIG. 26 is a perspective view illustrating a first example of a configuration of a solid-state imaging device according to a fifth embodiment.

FIG. 27 is a perspective view illustrating a second example of a configuration of a solid-state imaging device according to the fifth embodiment.

FIG. 28 is a perspective view illustrating a third example of a configuration of a solid-state imaging device according to the fifth embodiment.

FIG. 29 is a perspective view illustrating a first example of a configuration of a solid-state imaging device according to a sixth embodiment.

FIG. 30 is a perspective view illustrating a second example of a configuration of a solid-state imaging device according to the sixth embodiment.

FIG. 31 is a perspective view illustrating a first example of a configuration of a solid-state imaging device according to a seventh embodiment.

FIG. 32 is a perspective view illustrating a second example of a configuration of a solid-state imaging device according to the seventh embodiment.

FIG. 33 is a cross-sectional view illustrating a first example of a configuration of a conductor and substrate according to an eighth embodiment.

FIG. 34 is an enlarged cross-sectional view illustrating an example of a configuration of a solid-state imaging device according to the eighth embodiment.

FIG. 35 is a cross-sectional view illustrating a second example of a configuration of a conductor and substrate according to the eighth embodiment.

FIG. 36 is a block diagram illustrating an example of a schematic configuration of a vehicle control system.

FIG. 37 is an explanatory diagram illustrating an example of installation positions of an outside-vehicle information detecting section and imaging sections.

### MODE FOR CARRYING OUT THE INVENTION

Hereinafter, embodiments of a solid-state imaging element and a manufacturing method for the solid-state imaging device will be described with reference to the drawings. Although main components of the solid-state imaging device will be mainly described below, the solid-state imaging device may have components and functions that are not illustrated or described. The following description does not exclude components and functions that are not illustrated or described.

### <Configuration Example of Solid-State Imaging Device>

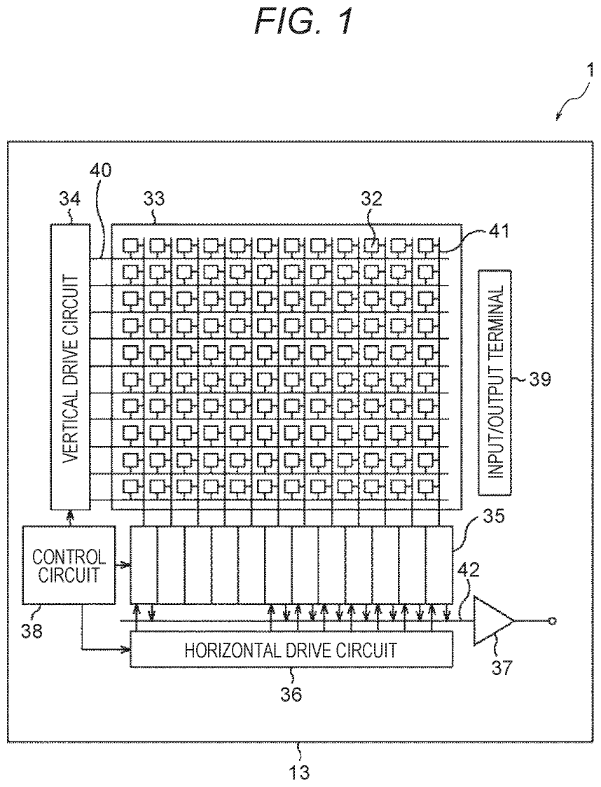

FIG. 1 illustrates a circuit configuration example of a substrate 13 of a solid-state imaging device 1.

The solid-state imaging device 1 includes a pixel array unit 33 in which a pixel 32 is disposed in a two-dimensional array, a vertical drive circuit 34, a column signal processing circuit 35, a horizontal drive circuit 36, an output circuit 37, a control circuit 38, and an input/output terminal 39. For example, components of the solid-state imaging device 1 are disposed on the substrate 13. Note that, hereinafter, each component such as the pixel array unit 33, the vertical drive circuit 34, the column signal processing circuit 35, the horizontal drive circuit 36, the output circuit 37, the control circuit 38, or the input/output terminal 39 may be referred to as an imaging element.

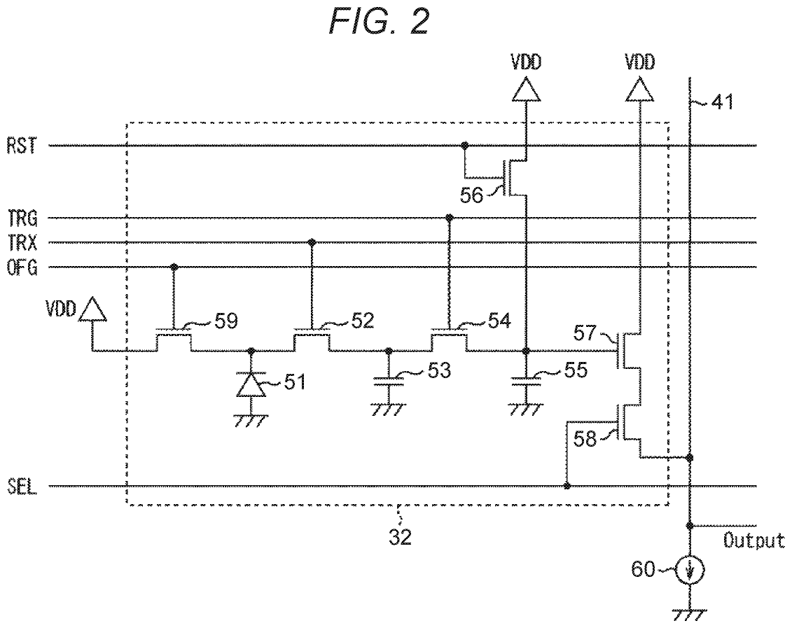

The pixel 32 includes a photodiode as a photoelectric conversion element and a plurality of pixel transistors. A circuit configuration example of the pixel 32 will be described later with reference to FIG. 2.

Furthermore, the pixel 32 may have a shared pixel structure. The shared pixel structure includes a plurality of photodiodes, a plurality of transfer transistors, one shared floating diffusion (floating diffusion region), and another pixel transistor shared by each of the transistors described above. That is, the shared pixel is configured such that the photodiodes and the transfer transistors configuring a plurality of unit pixels share other pixel transistors, respectively.

The control circuit 38 receives an input clock and data giving a command of an operation mode and the like and outputs data of internal information and the like of the solid-state imaging device 1. That is, the control circuit 38 generates a clock signal and a control signal which serve as a reference for operations of the vertical drive circuit 34, column signal processing circuit 35, horizontal drive circuit 36 and the like on the basis of a vertical synchronization signal, a horizontal synchronization signal, and a master clock. Then, the control circuit 38 outputs the generated clock signal and control signal to the vertical drive circuit 34, the column signal processing circuit 35, the horizontal drive circuit 36, and the like.

For example, the vertical drive circuit 34 includes a shift register, selects a predetermined pixel drive wiring 40, supplies a pulse for driving the pixel 32 to the selected pixel drive wiring 40, and drives the pixel 32 row by row. That is, the vertical drive circuit 34 sequentially selects and scans each pixel 32 in the pixel array unit 33 row by row in a vertical direction and supplies a pixel signal based on signal charge generated according to a light amount received by a photoelectric conversion unit of each pixel 32 to the column signal processing circuit 35 through a vertical signal line 41.

The column signal processing circuit 35 is disposed for each column of the pixel 32 and performs signal processing such as noise removal on the signal output from the pixel 32 of one row for each pixel column. For example, the column signal processing circuit 5 performs signal processing such as correlated double sampling (CDS) for removing a fixed pattern noise specific to the pixel and AD conversion.

For example, the horizontal drive circuit 36 including a shift register sequentially selects the column signal processing circuit 35 by sequentially outputting a horizontal scanning pulse and outputs the pixel signal from each of the column signal processing circuits 35 to a horizontal signal line 42.

The output circuit 37 performs the signal processing on the signal sequentially supplied from each of the column signal processing circuits 35 through the horizontal signal line 42, and outputs the processed signal. For example, there is a case where the output circuit 37 performs only buffering, or a case where the output circuit 37 performs black level adjustment, column variation correction, various types of digital signal processing, and the like. The input/output terminal 39 exchanges signals with the outside.

The solid-state imaging device 1 as described above is a CMOS image sensor referred to as a column AD type in which the column signal processing circuit 35 which performs CDS processing and AD conversion processing is disposed for each pixel column.

### <Circuit Configuration Example of Pixel>

FIG. 2 illustrates an equivalent circuit of the pixel 32.

The pixel 32 illustrated in FIG. 2 illustrates a configuration that implements an electronic global shutter function.

The pixel 32 includes a photodiode 51 as a photoelectric conversion element, a first transfer transistor 52, a memory unit (MEM) 53, a second transfer transistor 54, a floating diffusion region (FD) 55, a reset transistor 56, an amplifier transistor 57, a selection transistor 58, and a discharge transistor 59.

The photodiode 51 is a photoelectric conversion unit that generates and accumulates charge (signal charge) corresponding to the received light amount. An anode terminal of the photodiode 51 is grounded, and a cathode terminal of the photodiode 51 is connected to the memory unit 53 via the first transfer transistor 52. Furthermore, the cathode terminal of the photodiode 51 is also connected to the discharge transistor 59 for discharging unnecessary charge.

When turned on by a transfer signal TRX, the first transfer transistor 52 reads the charge generated by the photodiode 51 and transfers the charge to the memory unit 53. The memory unit 53 is a charge holding unit that temporarily holds charge until the charge is transferred to the FD 55.

When turned on by a transfer signal TRG, the second transfer transistor 54 reads the charge held in the memory unit 53 and transfers the charge to the FD 55.

The FD 55 is a charge holding unit that holds the charge read from the memory unit 53 in order to read the charge as a signal. When turned on by a reset signal RST, the reset transistor 56 resets the potential of the FD 55 by discharging the charge accumulated in the FD 55 to a constant voltage source VDD.

The amplifier transistor 57 outputs a pixel signal corresponding to the potential of the FD 55. That is, the amplifier transistor 57 constitutes a source follower circuit with a load MOS 60 as a constant current source, and a pixel signal indicating a level according to the charge accumulated in the FD 55 is output from the amplifier transistor 57 to the column signal processing circuit 35 (FIG. 1) via the selection transistor 58. The load MOS 60 is disposed, for example, in the column signal processing circuit 35.

The selection transistor 58 is turned on when the pixel 32 is selected by a selection signal SEL, and outputs a pixel signal of the pixel 32 to the column signal processing circuit 35 via the vertical signal line 41.

When turned on by a discharge signal OFG, the discharge transistor 59 discharges unnecessary charge accumulated in the photodiode 51 to the constant voltage source VDD.

The transfer signals TRX and TRG, the reset signal RST, the discharge signal OFG, and the selection signal SEL are supplied from the vertical drive circuit 34 via the pixel drive wiring 40.

The operation of the pixel 32 will be briefly described.

First, before exposure is started, the discharge transistor 59 is turned on when the discharge signal OFG at a high level is supplied to the discharge transistor 59, the charge accumulated in the photodiode 51 is discharged to the constant voltage source VDD, and the photodiodes 51 of all the pixels are reset.

After the photodiode 51 is reset, when the discharge transistor 59 is turned off by the discharge signal OFG at a low level, the exposure is started in all the pixels of the pixel array unit 33.

When a predetermined exposure time has elapsed, the first transfer transistor 52 is turned on by the transfer signal TRX in all the pixels of the pixel array unit 33, and the charge accumulated in the photodiode 51 is transferred to the memory unit 53.

After the first transfer transistor 52 is turned off, the charge held in the memory unit 53 of each pixel 32 is sequentially read row by row by the column signal processing circuit 35. In the read operation, the second transfer transistor 54 of the pixel 32 of a read row is turned on by the transfer signal TRG, and the charge held in the memory unit 53 is transferred to the FD 55. Then, when the selection transistor 58 is turned on by the selection signal SEL, a signal indicating a level corresponding to the charge accumulated in the FD 55 is output from the amplifier transistor 57 to the column signal processing circuit 35 via the selection transistor 58.

As described above, in the pixel 32 having the pixel circuit of FIG. 2, the exposure time is set to be the same in all the pixels of the pixel array unit 33, and after the exposure is finished, the charge is temporarily held in the memory unit 53, and a global shutter operation (imaging) of sequentially reading the charge from the memory unit 53 row by row is possible.

Note that the circuit configuration of the pixel 32 is not limited to the configuration illustrated in FIG. 2, and for example, a circuit configuration in which the operation by a so-called rolling shutter system is performed without the memory unit 53 can be adopted.

### First Embodiment

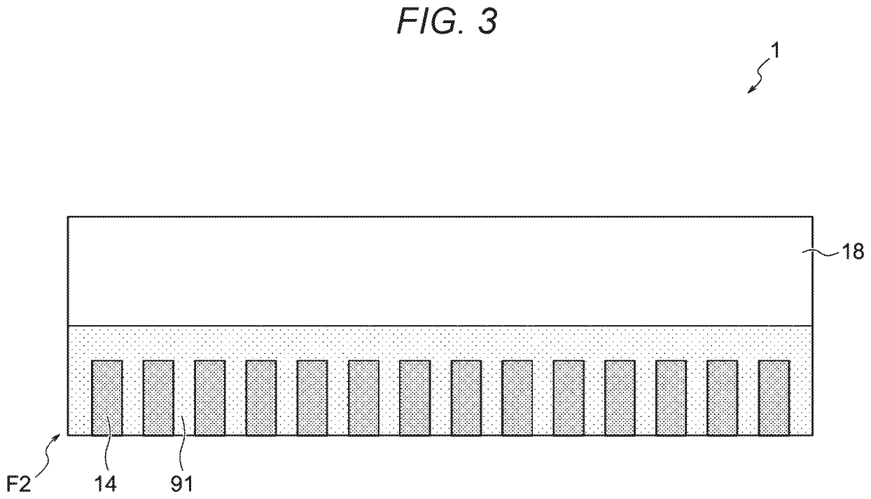

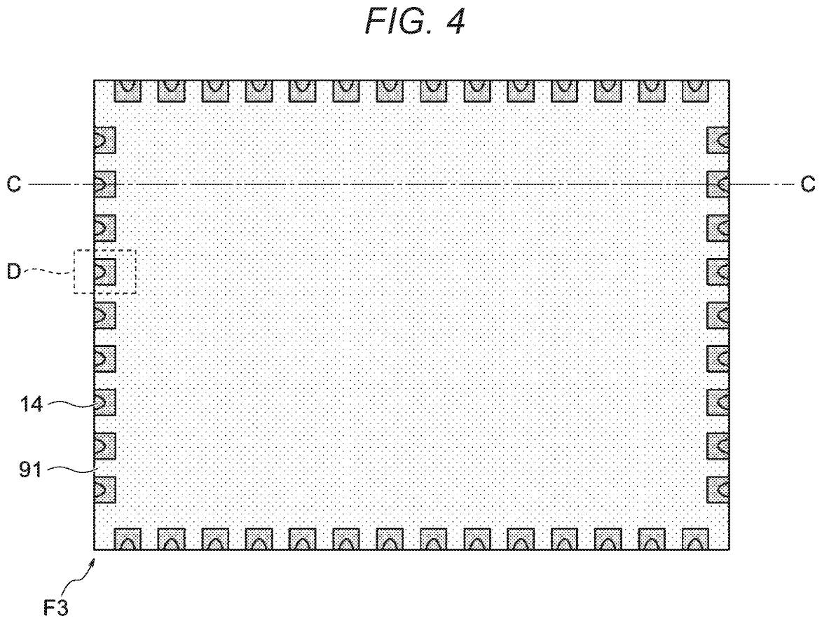

FIG. 3 is a side view illustrating an example of an external configuration of the solid-state imaging device 1 according to the first embodiment. FIG. 4 is a plan view illustrating an example of the external configuration of the solid-state imaging device 1 according to the first embodiment.

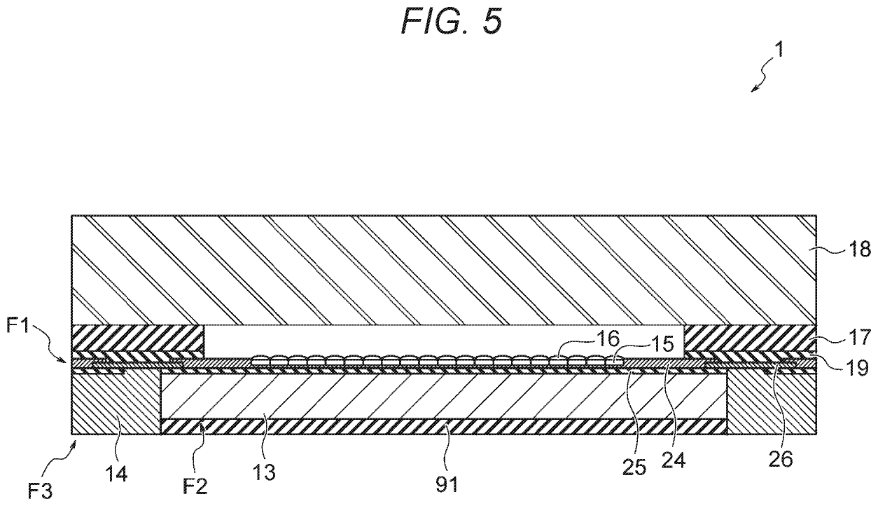

FIG. 3 and FIG. 4 are external views illustrating a semiconductor package of the solid-state imaging device 1 as viewed from a package side surface and a package back surface, respectively. Note that line C-C in FIG. 4 illustrates a cross section corresponding to FIG. 5 which is a cross-sectional view.

FIG. 5 is a cross-sectional view illustrating an example of a configuration of the solid-state imaging device 1 according to the first embodiment.

The solid-state imaging device 1 includes a substrate 13, a conductor 14, and a protective substrate 18.

The solid-state imaging device 1 illustrated in FIG. 5 is a semiconductor package in which the substrate 13 is packaged. Components (imaging elements) of the solid-state imaging device 1 illustrated in FIG. 1 are disposed on the substrate 13. More specifically, the solid-state imaging device 1 has a chip size package (CSP) structure. That is, the package outer edge of the solid-state imaging device 1 substantially matches the outer edge of the substrate 13 as viewed in a normal direction of the substrate surface of the substrate 13. In this configuration, a back surface F2 and side surface F3 of the substrate 13 are also a back surface and side surface of the package, respectively.

The substrate 13 has a front surface (first surface) F1, a back surface (second surface) F2, and a side surface F3. The back surface F2 is a surface opposite to the front surface F1. The side surface F3 is a surface continuous from the back surface F2. Furthermore, the substrate 13 includes an imaging element that generates an electric signal obtained by photoelectrically converting light incident on the front surface F1.

In the substrate 13, a plurality of conductors 14, which are external terminals for electrical connection with an external substrate (not illustrated), is disposed. More specifically, the conductor 14 is, for example, a conductive pad.

Furthermore, the conductor 14 is disposed on at least one of the back surface F2 or the side surface F3. In the example illustrated in FIG. 5, the conductor 14 is disposed on both the lower surface (back surface F2) and the side surface F3 of the substrate 13. Furthermore, the conductor 14 is electrically connected to the imaging element.

On the upper surface (front surface F1) of the substrate 13, a red (R), green (G), or blue (B) color filter 15 and an on-chip lens 16 are disposed. The protective substrate 18 is, for example, a transparent glass substrate. When hardness of the protective substrate 18 is higher than that of the on-chip lens 16, an effect of protecting the on-chip lens 16 is enhanced.

Furthermore, the solid-state imaging device 1 further includes a resin layer 17, an adhesive layer 19, an organic film 24, an insulating layer 25, a connection pad 26, and a resin layer (insulating layer) 91.

The resin layer 17 supports the protective substrate 18 such that a gap is provided between the protective substrate 18 and the on-chip lens 16. In this configuration, the solid-state imaging device 1 has a cavity structure. The resin layer 17 has, for example, a columnar or wall-like structure.

The adhesive layer 19 bonds the substrate 13 to the resin layer 17.

The organic film 24 includes the photodiode 51. In this case, the photodiode 51 is an organic photodiode including an organic material. The organic film 24 may include a wiring layer. This wiring layer includes, for example, a pixel circuit.

The insulating layer 25 is, for example, a silicon oxide film.

The connection pad (signal output unit) 26 transmits and receives a signal to and from the imaging element. The substrate 13 has, for example, the connection pads 26 on the substrate 13 or in the substrate 13.

The resin layer 91 is disposed on the lower surface (back surface F2) of the substrate 13. The resin layer 91 is, for example, a protective resin film such as a solder resist. The conductor 14 is disposed so as to be exposed from the resin layer 91.

As illustrated in FIG. 4, the conductor 14 is disposed along the outer edge of the package as viewed from the back surface F2. Furthermore, as illustrated in FIG. 3, the conductor 14 is also disposed on the side surface F3 so as to extend from the back surface F2.

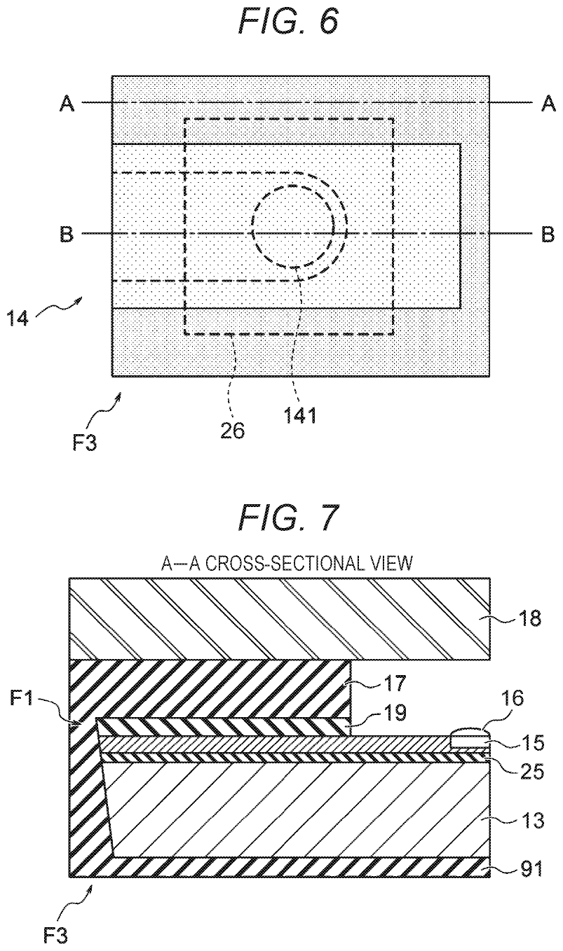

FIG. 6 is an enlarged plan view in which the conductor 14 and a periphery of the conductor 14 in a broken-line frame D of FIG. 4 are enlarged.

FIG. 7 is an enlarged cross-sectional view illustrating a configuration of the solid-state imaging device 1 in a cross section taken along line A-A in FIG. 6.

As described above, since the solid-state imaging device 1 has a CSP structure, the package side surface is substantially the same as the side surface F3 of the substrate. The side surface F3 of the substrate 13 is covered with the resin layer 91.

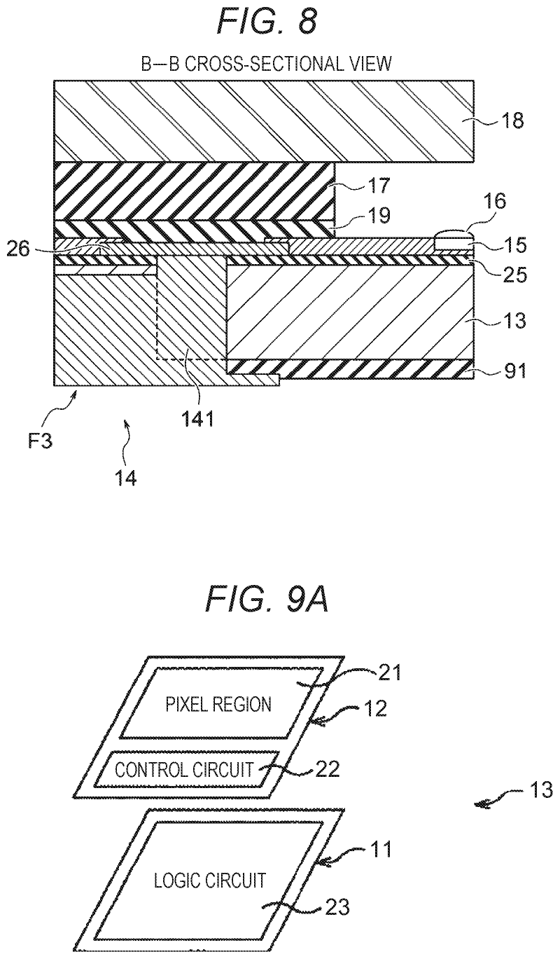

FIG. 8 is an enlarged cross-sectional view illustrating a configuration of the solid-state imaging device 1 in a cross section taken along line B-B in FIG. 6.

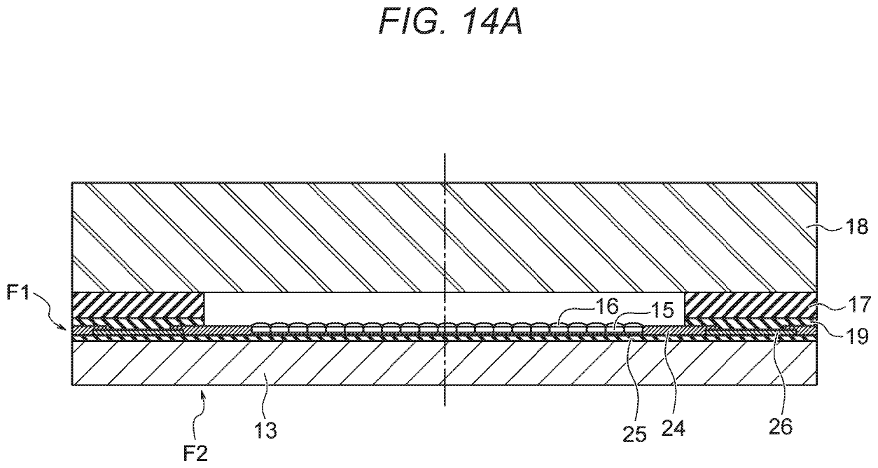

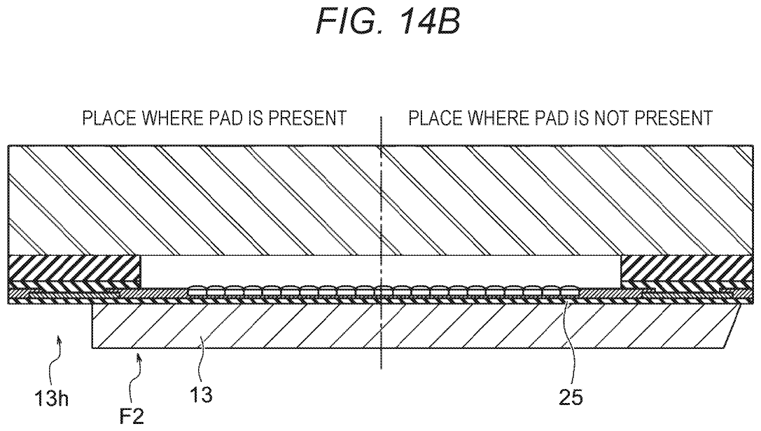

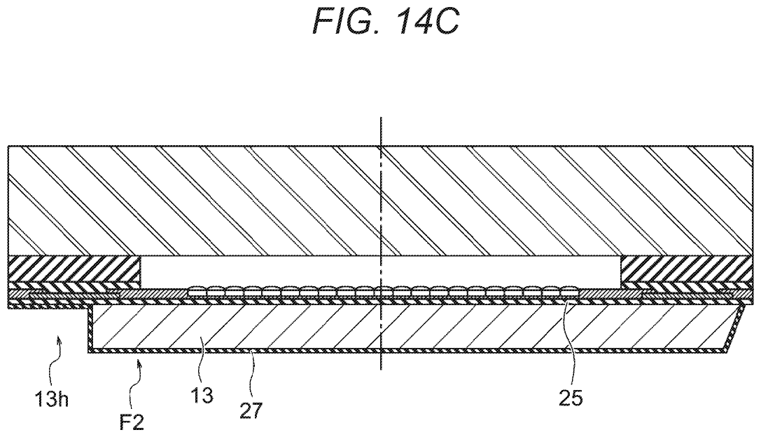

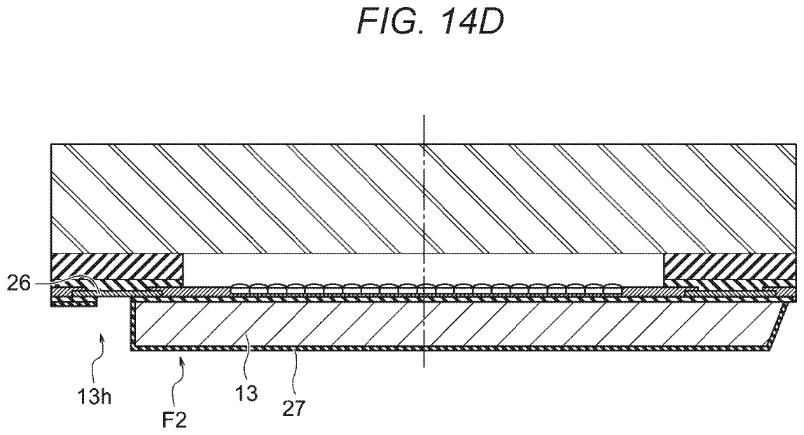

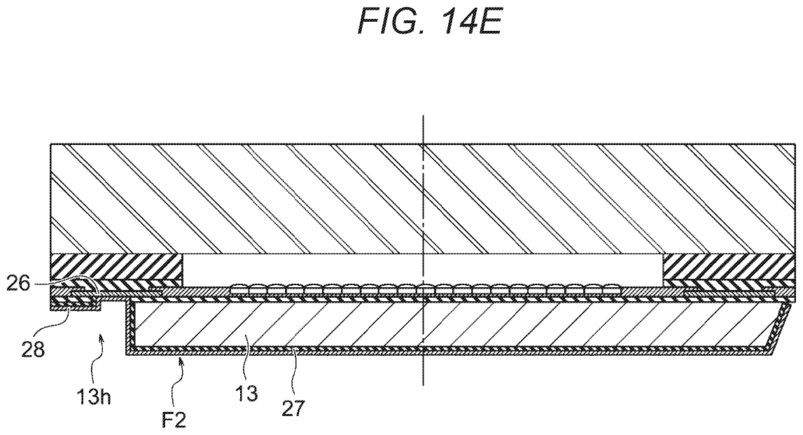

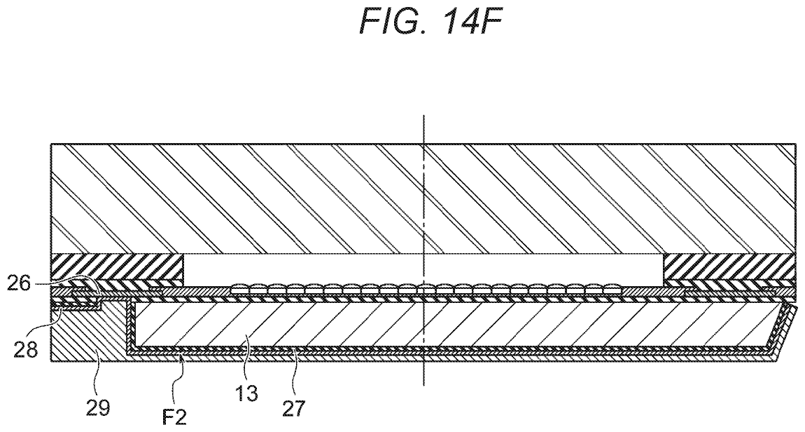

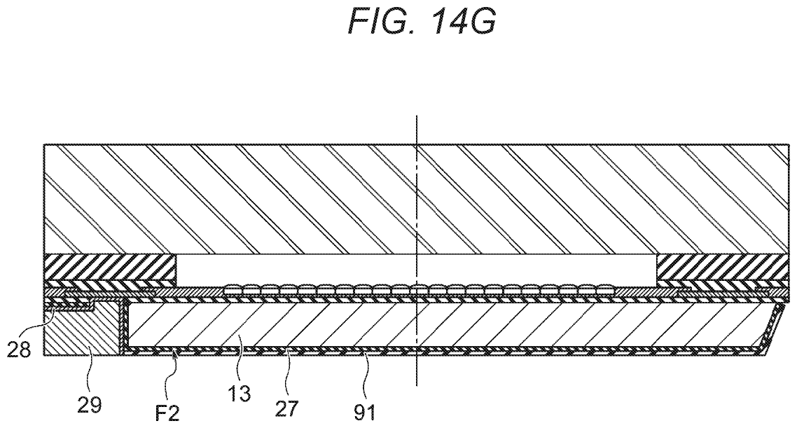

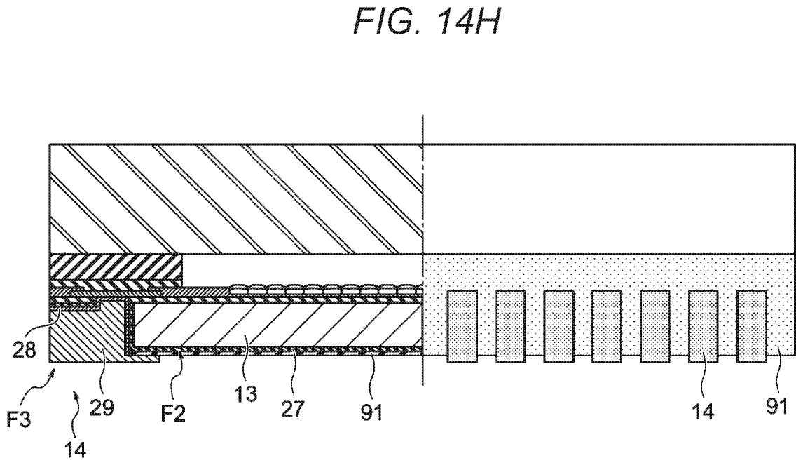

The solid-state imaging device 1 further includes a contact member 141. The contact member 141 is, for example, a through via. The contact member 141 extends in a depth direction of the substrate 13 and is electrically connected to the imaging element. The conductor 14 is electrically connected to the contact member 141. For example, the contact member 141 is formed integrally with the conductor 14 as will be described later with reference to FIGS. 14A to 14H. In the example illustrated in FIG. 8, the contact member 141 is disposed so as to penetrate both the substrate 13 and the insulating layer 25. The connection pad 26 is connected to one end of the contact member 141. In the example illustrated in FIG. 8, one end of the contact member 141 is electrically connected to the lower surface of the connection pad 26. The other end and the side surface of the contact member 141 is electrically connected to the conductor 14. Therefore, the contact member 141 electrically connects the connection pad 26 and the conductor 14.

As illustrated in FIG. 6, the contact member 141 as viewed from the back surface F2 side is disposed inside the outer edge of the connection pad 26. The conductor 14 is disposed so as to be exposed from the contact member 141 to the side surface F3 (package side surface). For example, the conductor 14 is formed by processing the substrate 13 from the contact member 141 toward the side surface F3 (package side surface). Note that in the examples illustrated in FIG. 6 and FIG. 8, the conductor 14 extends along the lower surface of the package so as to cover the resin layer 91.

Next, a case where the substrate 13 is a stacked substrate will be described.

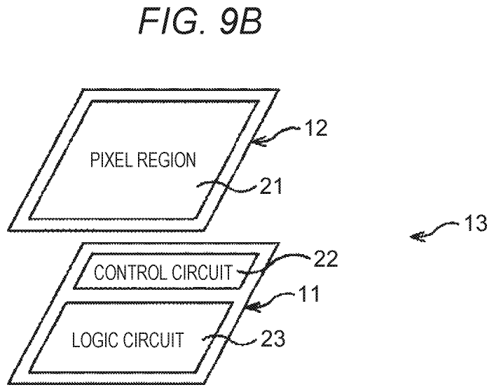

FIG. 9A and FIG. 9B are diagrams illustrating a configuration example of the substrate 13.

The substrate 13 is a stacked substrate configured by stacking a lower-side substrate 11 and an upper-side substrate 12.

As illustrated in FIG. 9A, the upper-side substrate 12 includes a pixel region 21 in which pixel units performing photoelectric conversion are two-dimensionally disposed and a control circuit 22 that controls the pixel units.

The lower-side substrate 11 includes a logic circuit 23 such as a signal processing circuit that processes a pixel signal output from each of the pixel units.

Alternatively, furthermore, as illustrated in FIG. 9B, the upper-side substrate 12 may include only the pixel region 21, and the lower-side substrate 11 may include the control circuit 22 and the logic circuit 23.

As described above, by forming and stacking the logic circuit 23 or both the control circuit 22 and the logic circuit 23 on the lower-side substrate 11 separately from the upper-side substrate 12 of the pixel region 21, the size of the solid-state imaging device 1 can be reduced as compared with a case where the pixel region 21, the control circuit 22, and the logic circuit 23 are disposed in one semiconductor substrate in the planar direction.

Hereinafter, the upper-side substrate 12 on which at least the pixel region 21 is formed will be referred to as a pixel sensor substrate 12, and the lower-side substrate 11 on which at least the logic circuit 23 is formed will be referred to as a logic substrate 11.

That is, the substrate 13 includes the pixel sensor substrate (first substrate) 12 and the logic substrate (second substrate) 11. On the pixel sensor substrate 12, the photodiode 51 that is a photoelectric conversion unit in the imaging element is disposed. The logic substrate 11 is stacked on the pixel sensor substrate 12 and performs signal processing on the electric signal photoelectrically converted by the photodiode 51.

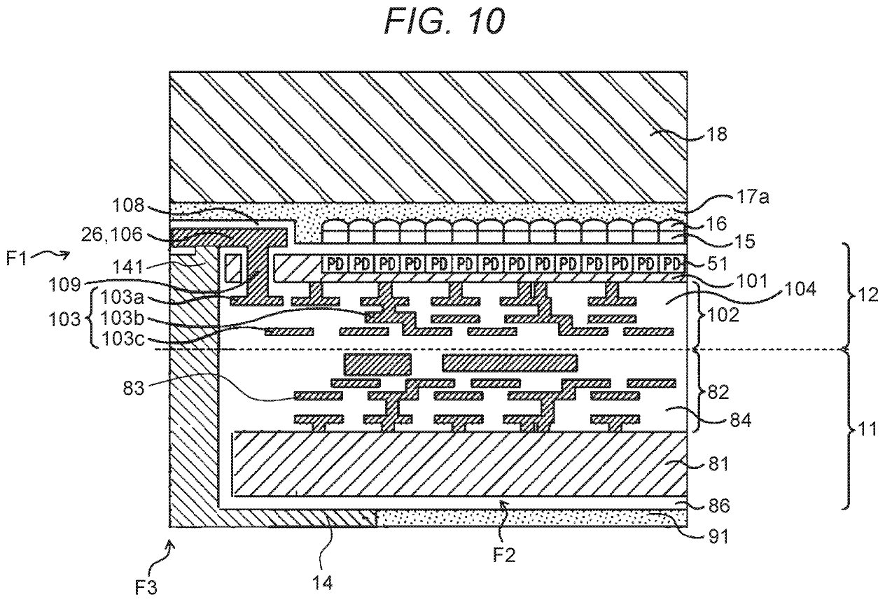

FIG. 10 is a cross-sectional view illustrating an example of a configuration of the solid-state imaging device 1 according to the first embodiment. Note that in an example illustrated in FIG. 10, the solid-state imaging device 1 has a cavity-less structure as will be illustrated in FIG. 15 of a modification example of the first embodiment to be described later. However, the present disclosure is not limited thereto, and the solid-state imaging device 1 may have a cavity structure.

For example, in the logic substrate 11, a multilayer wiring layer 82 is formed on the upper side (pixel sensor substrate 12 side) of a semiconductor substrate 81 (hereinafter, referred to as a silicon substrate 81) including silicon (Si). The multilayer wiring layer 82 is formed as the control circuit 22 and logic circuit 23 illustrated in FIG. 9A and FIG. 9B.

The multilayer wiring layer 82 includes a plurality of wiring layers 83 including an uppermost wiring layer 83 closest to the pixel sensor substrate 12, an intermediate wiring layer 83, and a lowermost wiring layer 83 closest to the silicon substrate 81, and an interlayer insulating film 84 formed between the wiring layers 83.

The plurality of wiring layers 83 is formed using, for example, copper (Cu), aluminum (Al), tungsten (W), or the like, and the interlayer insulating film 84 is formed using, for example, a silicon oxide film, a silicon nitride film, or the like. In each of the plurality of wiring layers 83 and the interlayer insulating film 84, all the layers may include the same material, or two or more materials may be used depending on the layer.

On the other hand, in the pixel sensor substrate 12, a multilayer wiring layer 102 is formed on the lower side (logic substrate 11 side) of a semiconductor substrate 101 (hereinafter, referred to as a silicon substrate 101) including silicon (Si). The multilayer wiring layer 102 is formed as the pixel circuit of the pixel region 21 in FIG. 9A and FIG. 9B.

The multilayer wiring layer 102 includes a plurality of wiring layers 103 including an uppermost wiring layer 103a closest to the silicon substrate 101, an intermediate wiring layer 103b and a lowermost wiring layer 103c closest to the logic substrate 11, and an interlayer insulating film 104 formed between the wiring layers 103.

As the material used for the plurality of wiring layers 103 and the interlayer insulating film 104, the same type of material as the material of the wiring layer 83 and the interlayer insulating film 84 described above can be adopted. Furthermore, the plurality of wiring layers 103 and the interlayer insulating film 104 are same as the wiring layer 83 and the interlayer insulating film 84 described above in that the plurality of wiring layers 103 and the interlayer insulating film 104 may be formed by using one or two or more materials.

Note that in the example of FIG. 10, the multilayer wiring layer 102 of the pixel sensor substrate 12 includes three wiring layers 103, and the multilayer wiring layer 82 of the logic substrate 11 includes four wiring layers 83. However, the total number of wiring layers is not limited thereto, and any number of wiring layers can be used.

In the silicon substrate 101, the photodiode 51 formed by a PN junction is formed for each pixel 32.

Furthermore, although not illustrated, a plurality of pixel transistors such as the first transfer transistor 52 and the second transfer transistor 54, a memory unit (MEM) 53, and the like, which is described with reference to FIG. 2, is also formed in the multilayer wiring layer 102 and the silicon substrate 101.

At a predetermined position of the silicon substrate 101 on which the color filter 15 and the on-chip lens 16 are not formed, a through silicon via 109 connected to the wiring layer 103a of the pixel sensor substrate 12 is formed.

The through silicon via 109 is connected by a connection wiring 106 (connection pad 26) formed on the upper surface of the silicon substrate 101. Furthermore, an insulating film 107 is formed between the through silicon via 109 and the silicon substrate 101. Moreover, on the upper surface of the silicon substrate 101, the color filter 15 and the on-chip lens 16 are formed via an insulating film (planarization film) 108.

As described above, the substrate 13 which is a stacked substrate has a stacked structure formed by bonding the multilayer wiring layer 82 side of the logic substrate 11 and the multilayer wiring layer 102 side of the pixel sensor substrate 12. In FIG. 10, a bonding surface between the multilayer wiring layer 82 of the logic substrate 11 and the multilayer wiring layer 102 of the pixel sensor substrate 12 is indicated by a broken line.

In the example illustrated in FIG. 10, the contact member 141 extends in the depth direction of the pixel sensor substrate 12 and logic substrate 11. Furthermore, the conductor 14 is disposed on both the side surface F3 of the logic substrate 11 and the side surface F3 of the pixel sensor substrate 12.

Note that in the example illustrated in FIG. 10, connection between the wiring layer 83 of the logic substrate 11 and at least one of the wiring layer 103 or conductor 14 of the pixel sensor substrate 12 is omitted.

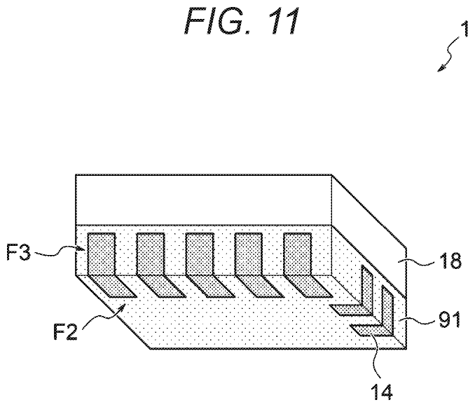

FIG. 11 is a perspective view illustrating an example of a configuration of the solid-state imaging device 1 according to the first embodiment.

The conductor 14 is in surface contact with at least one of the back surface F2 or the side surface F3. In the example illustrated in FIG. 11, the conductor 14 is disposed so as to be in surface contact with both the back surface F2 and side surface F3 of the substrate 13. More specifically, on at least one of the back surface F2 or the side surface F3, the arrangement place of the conductor 14 is flush with the other places. In the example illustrated in FIG. 11, the conductor 14 is exposed from the resin layer 91 disposed substantially flush with both the back surface F2 (package back surface) and the side surface F3 (package side surface).

Furthermore, the conductor 14 is disposed continuously from the back surface F2 to the side surface F3. That is, the conductor 14 disposed on the back surface F2 and the conductor 14 disposed on the side surface F3 are electrically connected at the corner where the side surface F3 and the back surface F2 intersect each other.

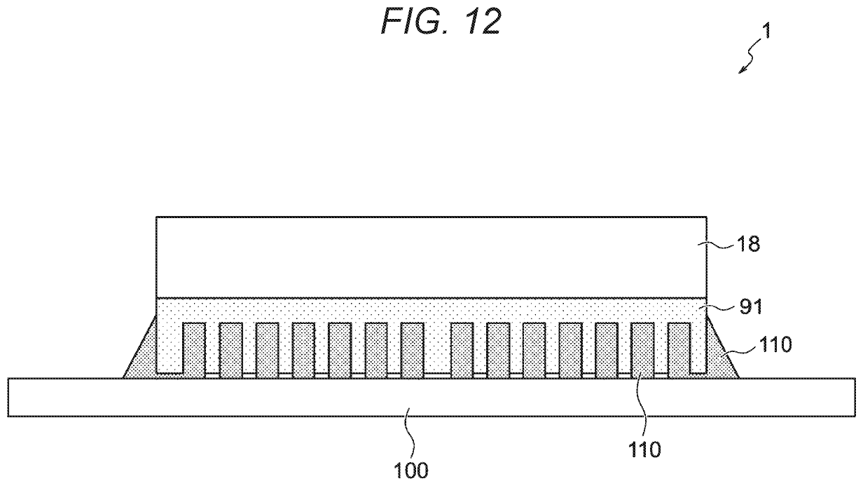

FIG. 12 is an external view illustrating an example of connection between the solid-state imaging device 1 and a mount substrate 100 according to the first embodiment.

The solid-state imaging device 1 is connected to the mount substrate 100 by, for example, solder 110. In the example illustrated in FIG. 12, the solder 110 is applied to the conductor 14 disposed on both the back surface F2 and the side surface F3. Therefore, the height from the mount substrate 100 to the upper surface of the protective substrate 18 can be further reduced.

### Comparative Example

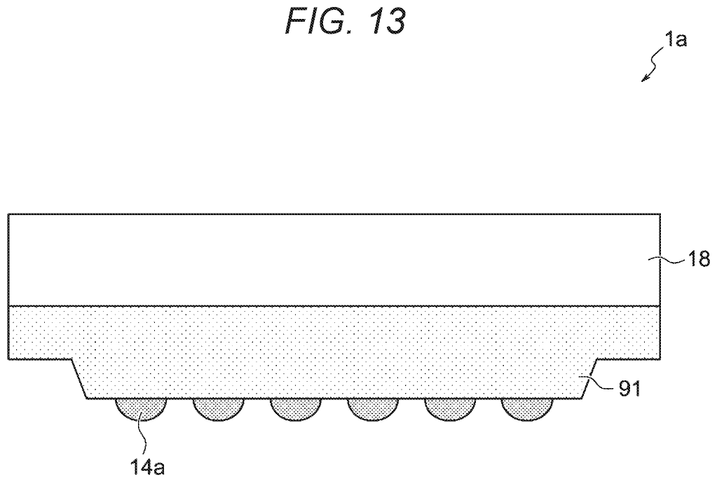

FIG. 13 is a view illustrating an example of a configuration of a solid-state imaging device 1a according to the comparative example. The comparative example is different from the first embodiment in that a metal bump 14a is provided instead of the conductor 14.

As illustrated in FIG. 13, a ball grid array (BGA) structure is known as one of the package structures. In the BGA structure, a plurality of metal bumps 14a is provided on the back surface of the substrate 13. Note that the metal bump 14a is, for example, a solder ball. However, depending on the height of the metal bump 14a, the height from the mount substrate 100 to the upper surface of the protective substrate 18 increases. This goes against the demand for reducing the package size. Furthermore, the BGA may affect the placing state of the package. The placing state of the package on the mount substrate 100 is affected by dicing accuracy, parallelism of the substrate, flatness of the BGA, and the like. The flatness of the BGA is, for example, a variation of each metal bump 14a. For example, in a case where the flatness of the BGA is deteriorated due to the variation of the metal bump 14a, there is a possibility that a soldering defect occurs. Furthermore, in a rewiring layer on the lower surface of the package, the wiring distance to the metal bump 14a may be long, and the wiring resistance may increase.

On the other hand, in the first embodiment, the BGA (metal bump 14a) is not provided. Therefore, the height of the package can be further reduced by the height of the metal bump 14a. For example, the solid-state imaging device 1 according to the first embodiment can be made about 20% thinner than the solid-state imaging device 1a according to the comparative example. Furthermore, the influence of the flatness of the BGA can be suppressed, and the placing state of the package can be improved. Furthermore, the conductor 14 is disposed from the connection pad 26 which is a sensor pad toward the outer periphery. Therefore, the wiring resistance caused by the rewiring layer for connection with the metal bump 14a can be suppressed.

### <Manufacturing Method for Solid-State Imaging Device>

FIGS. 14A to 14H are cross-sectional views illustrating an example of the manufacturing method for the solid-state imaging device 1 according to the first embodiment.

Note that although only one chip is illustrated in FIGS. 14A to 14H, the substrate 13 is in a state of a wafer before being divided into individual pieces. In FIG. 14H, the substrate 13 is diced along a dividing region (scribe line) to be divided into individual pieces. The dividing regions are left and right ends of the substrate 13 in FIGS. 14A to 14H. Furthermore, in FIG. 14A to 14G, the left side from the center line indicates a region where the conductor 14 is provided, and the right side from the center line indicates a region where the conductor 14 is not provided. In FIG. 14H, the left side from the center line illustrates a cross-sectional view of the conductor 14, and the right side from the center line illustrates an external side view of the solid-state imaging device 1.

First, as illustrated in FIG. 14A, an imaging element is formed on the front surface F1 of the substrate 13 before being divided into individual pieces. Thereafter, the protective substrate 18 is attached above the front surface F1 of the substrate 13. Furthermore, back grinding or etching is performed from the back surface F2 side to make the substrate 13 thin.

Next, as illustrated in FIG. 14B, a hole 13h is formed in the substrate 13 by etching. The hole 13h is formed in a region partially including the connection pad 26 and the dividing region when viewed from the back surface F2 of the substrate 13. The insulating layer is exposed from the hole 13h.

Next, as illustrated in FIG. 14C, an insulating layer 27 is formed on the hole 13h, the back surface F2, and the insulating layer 25 from the back surface F2 side. The insulating layer 27 is, for example, a silicon oxide film. The insulating layer 27 is formed by, for example, chemical vapor deposition (CVD).

Next, as illustrated in FIG. 14D, the insulating layers 25 and 27 are etched so as to expose the connection pad 26. In this manner, the hole 13h extending in the depth direction of the substrate 13 from the back surface F2 side of the substrate 13 is formed so as to expose the connection pad 26.

Next, as illustrated in FIG. 14E, a seed layer 28 is formed on the connection pad 26 and the insulating layer 27 from the back surface F2 side. The material of the seed layer 28 is, for example, Ti or Cu.

Next, as illustrated in FIG. 14F, a metal layer 29 is formed on the seed layer 28 from the back surface F2 side. The metal layer 29 is formed so as to fill the hole 13h. That is, by forming the metal layer 29 from the back surface F2 side of the substrate 13 so as to fill the hole 13h, the contact member 141 extending in the depth direction of the substrate 13 and the conductor 14 electrically connected to the contact member 141 are formed. The metal layer 29 is, for example, a plating layer. The material of the metal layer 29 is, for example, Cu, Ni, or Au. Cu may be formed by electroplating, or Ni or Au may be formed by electroless plating.

Next, as illustrated in FIG. 14G, patterning is performed to remove a seed layer 28 and metal layer 29 which are unnecessary. Thereafter, the resin layer 91 is formed on the insulating layer 27 from the back surface F2 side. The resin layer 91 is formed avoiding the conductor 14. The resin layer 91 is a protective resin, and, for example, a solder resist. Furthermore, the rewiring layer may be formed on the back surface F2. The rewiring layer is formed by, for example, a photolithography technique using resist patterning and a plating method.

Next, as illustrated in FIG. 14H, the solid-state imaging device 1 is divided into individual pieces by dicing the substrate 13 along the dividing region. Thus, the conductor 14 disposed on at least one of the back surface F2 or the side surface F3 and electrically connected to the imaging element is formed. As a result, the solid-state imaging device 1 illustrated in FIGS. 3 to 8 is completed. In this configuration, the solid-state imaging device 1 is a wafer level chip size package (WLCSP).

As described above, according to the first embodiment, the conductor 14 is formed on at least one of the back surface F2 or the side surface F3. Therefore, the height of the package can be further reduced.

### Modification Example of First Embodiment

FIG. 15 is a cross-sectional view illustrating a first modification example of a configuration of the solid-state imaging device 1 according to the first embodiment. The first modification example is different from the first embodiment in that the package has a cavity-less structure.

The solid-state imaging device 1 further includes a resin layer 17a. Furthermore, in the example illustrated in FIG. 15, the resin layer 17 and the adhesive layer 19 in FIG. 5 of the first embodiment are not provided. The resin layer 17a is, for example, a glass seal resin. In the cavity-less structure, the resin layer 17 is not provided, and thus the height of the package can be further reduced.

### Second Embodiment

FIG. 16 is an enlarged cross-sectional view illustrating an example of a configuration of a solid-state imaging device 1 according to the second embodiment. The second embodiment is different from the first embodiment in that the conductor 14 on the side surface F3 is connected to the connection pad 26 via the conductor 14 on the back surface F2.

In the example illustrated in FIG. 16, one end of the contact member 141 is electrically connected to the lower surface of the connection pad 26. The other end of the contact member 141 is electrically connected to the conductor 14 disposed on the back surface F2. The conductor 14 disposed on the back surface F2 is electrically connected at a corner where the back surface F2 and the side surface F3 intersect each other. The conductor 14 disposed on the side surface F3 is disposed until reaching the resin layer 17.

Note that although not illustrated, as another example of the fourth embodiment, the conductor 14 may be disposed only on the package side surface by patterning the rewiring layer using the resin layer 91.

Next, a case where the substrate 13 is a stacked substrate will be described.

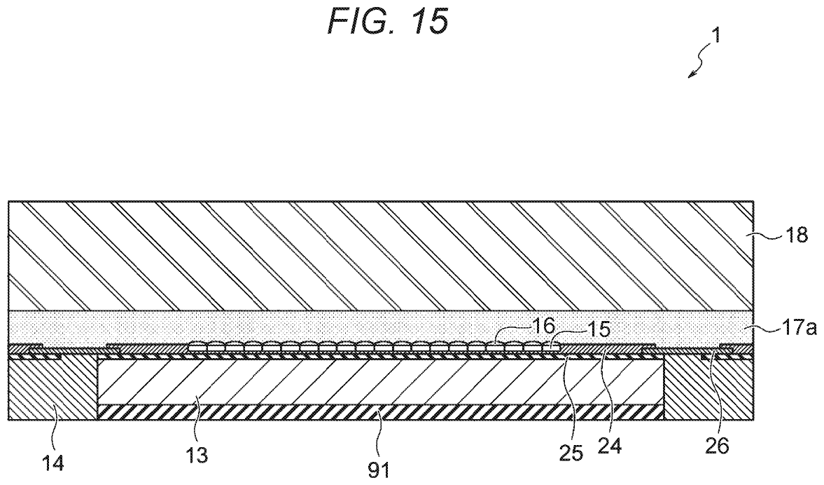

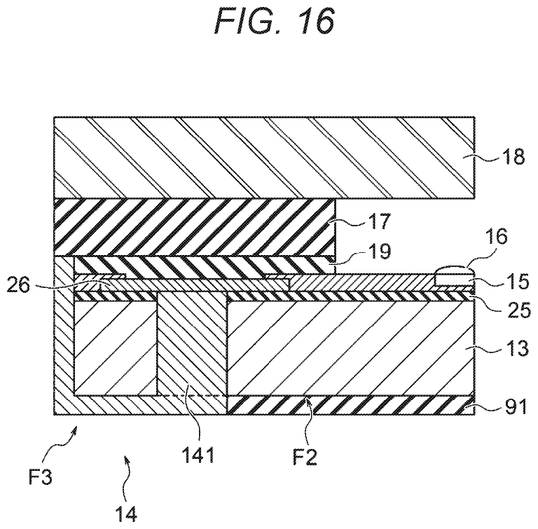

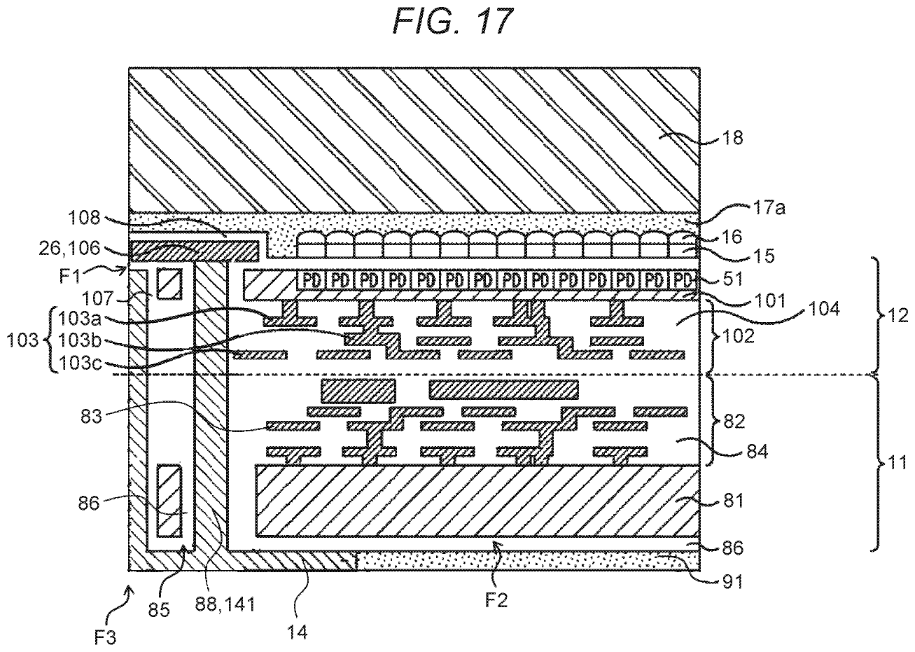

FIG. 17 is a cross-sectional view illustrating an example of a configuration of the solid-state imaging device 1 according to the second embodiment.

A silicon through hole 85 penetrating the silicon substrate 81 is formed at a predetermined position of the silicon substrate 81, and a connection conductor (for example, the metal layer 29) is embedded in an inner wall of the silicon through hole 85 via an insulating film 86 to form a through silicon via (TSV) 88 (contact member 141). The insulating film 86 may be formed using, for example, an SiO₂ film, a SiN film, and the like.

In the example illustrated in FIG. 17, the conductor 14 is disposed on the side surface F3 of the logic substrate 11, the side surface F3 of the pixel sensor substrate 12, and the back surface F2 of the logic substrate 11. Note that the conductor 14 may be disposed on any one of the side surfaces of the logic substrate 11 and pixel sensor substrate 12 as the side surface F3.

Note that in the example illustrated in FIG. 17, the connection among the connection pad 26, the wiring layer 83 of the logic substrate 11, and the wiring layer 103 of the pixel sensor substrate 12 is omitted.

In the example illustrated in FIG. 17, as in FIG. 10, the conductor 14 is disposed on the side surface F3 of the logic substrate 11, the side surface F3 of the pixel sensor substrate 12, and the back surface F2 of the logic substrate 11.

Next, the manufacturing method for the solid-state imaging device 1 is described.

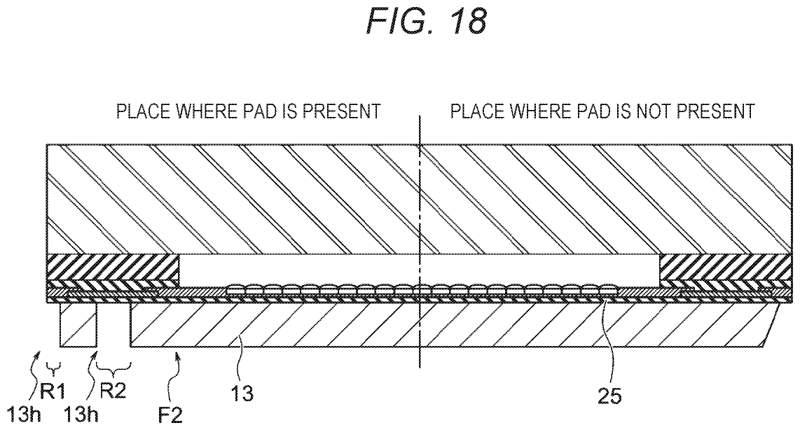

FIG. 18 is a cross-sectional view illustrating an example of the manufacturing method for the solid-state imaging device 1 according to the second embodiment.

As illustrated in FIG. 18, after the process illustrated in FIG. 14A, the holes 13h are respectively formed in a first region R1 including a part of the dividing region and a second region R2 including a part of the connection pad 26 as viewed from the back surface F2. In the process of FIG. 14F, the metal layer 29 is formed so as to fill the holes 13h in both the first region R1 and the second region R2. Therefore, the conductor 14 and contact member 141 disposed on the side surface F3 are formed. The other processes are similar to those of the first embodiment.

### Modification Example of Second Embodiment

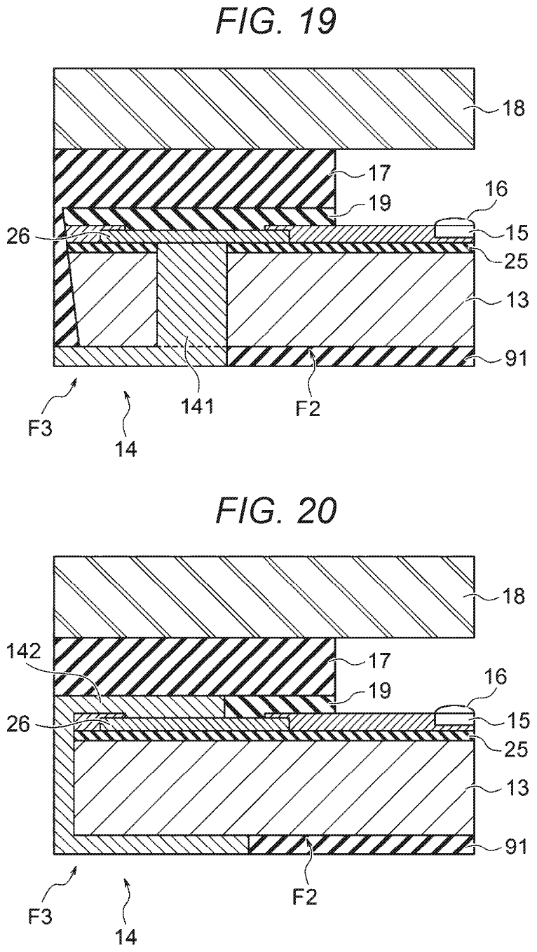

FIG. 19 is an enlarged cross-sectional view illustrating the modification example of the configuration of the solid-state imaging device 1 according to the second embodiment. The modification example of the second embodiment is different from the second embodiment in that the conductor 14 is not provided on the side surface F3.

### Third Embodiment

FIG. 20 is an enlarged cross-sectional view illustrating an example of a configuration of the solid-state imaging device 1 according to the third embodiment. The third embodiment is different from the first embodiment in that the connection pad 26 is connected to the conductor 14 via the upper surface (front surface).

The solid-state imaging device 1 further includes a conductive connection portion 142. The conductive connection portion 142 is, for example, a wiring. The conductive connection portion 142 is disposed on the front surface F1. In the example illustrated in FIG. 20, one end of the conductive connection portion 142 is electrically connected to the upper surface of the connection pad 26. The other end of the conductive connection portion 142 is electrically connected to the conductor 14 disposed on the side surface F3. Therefore, the conductive connection portion 142 electrically connects the connection pad 26 and the conductor 14.

In the first embodiment and the second embodiment, the connection pad 26 and the conductor 14 are connected on the lower surface of the connection pad 26. Here, for example, in a case where the solid-state imaging device 1 is a stacked sensor, there is a logic circuit for processing a pixel signal below the connection pad 26, and thus it is necessary to exclusively design the connection pad 26 for contact (for example, refer to FIG. 10 of the first embodiment and FIG. 17 of the second embodiment).

On the other hand, in the third embodiment, the connection pad 26 is electrically connected to the conductive connection portion 142 on the opposite side to the substrate 13. Thus, the connection pad 26 can be electrically connected to the conductor 14 without passing through the inside of the substrate 13 below the conductor 14. Therefore, even in a case where the solid-state imaging device 1 is the stacked sensor, dedicated design of the connection pad 26 becomes unnecessary.

Next, a case where the substrate 13 is a stacked substrate will be described.

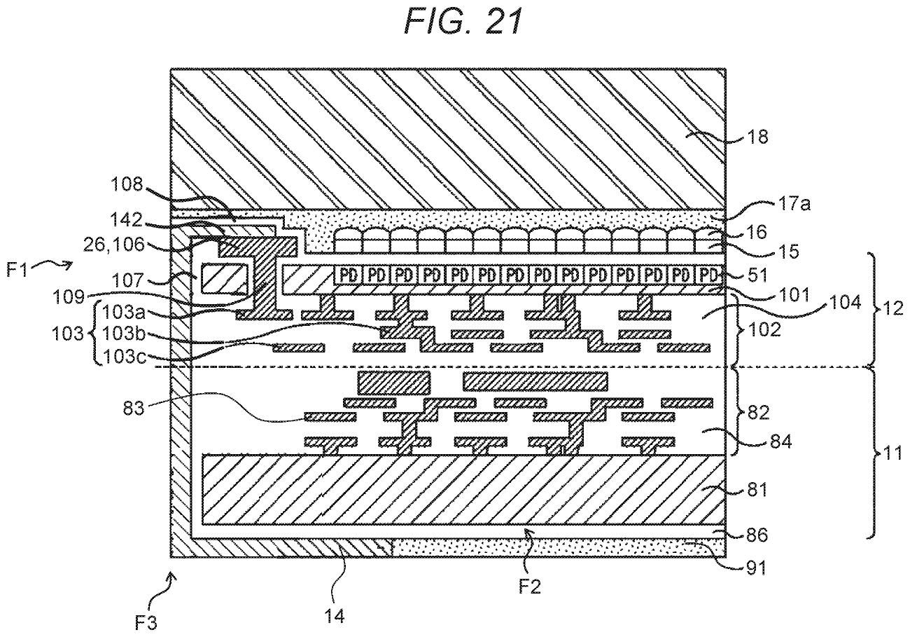

FIG. 21 is a cross-sectional view illustrating an example of a configuration of the solid-state imaging device 1 according to the third embodiment.

In the example illustrated in FIG. 21, the pixel sensor substrate 12 includes the connection pad 26 and a conductive connection portion 142. The conductive connection portion 142 is electrically connected to the connection pad 26 and extends to the side surface of the pixel sensor substrate 12. The conductor 14 is connected to the conductive connection portion 142 and disposed on the side surface of the pixel sensor substrate 12. Furthermore, the conductor 14 may be disposed on the side surface and lower surface of the logic substrate 11.

Note that in the example illustrated in FIG. 21, the connection pad 26 and the conductive connection portion 142 are disposed in the pixel sensor substrate 12. However, the present disclosure is not limited thereto, and the connection pad 26 and the conductive connection portion 142 may be disposed in the logic substrate 11. In this case, the conductive connection portion 142 extends to the side surface of the logic substrate 11. The conductor 14 is disposed on the side surface of the logic substrate 11. Furthermore, the conductor 14 may be disposed on the side surface of the pixel sensor substrate 12 and the lower surface of the logic substrate 11.

Next, a manufacturing method for the solid-state imaging device 1 according to the third embodiment will be described.

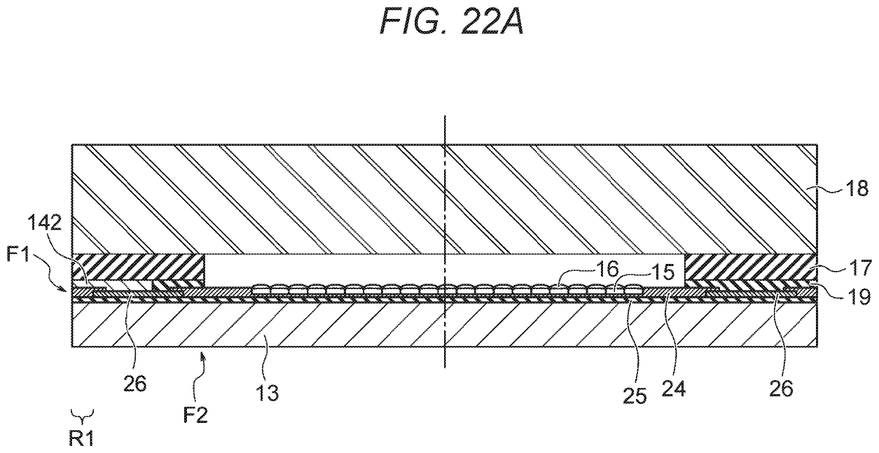

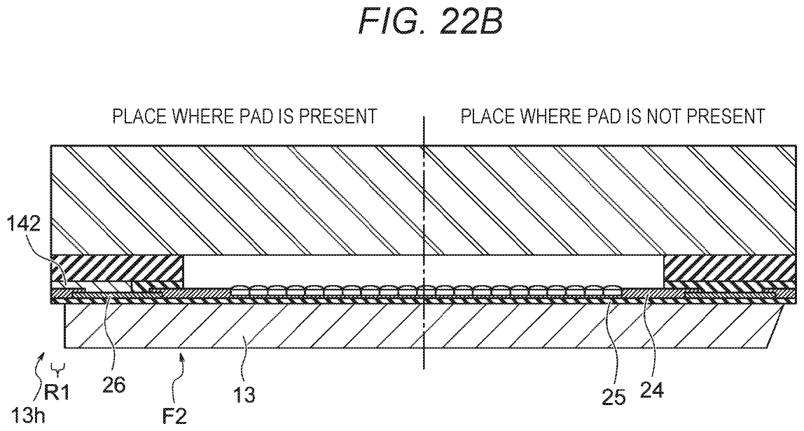

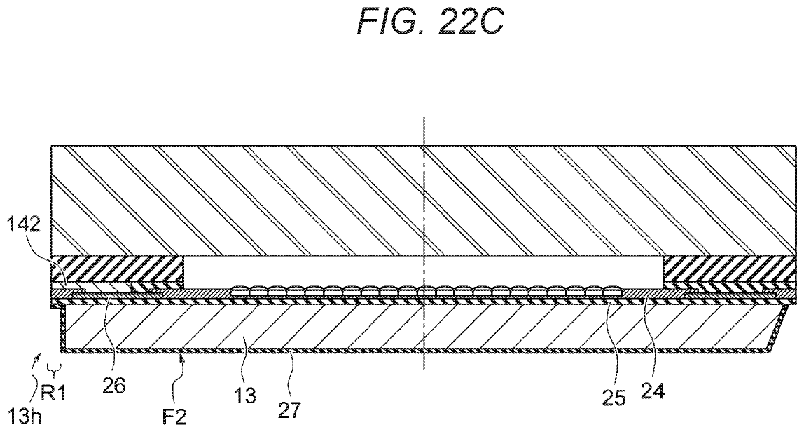

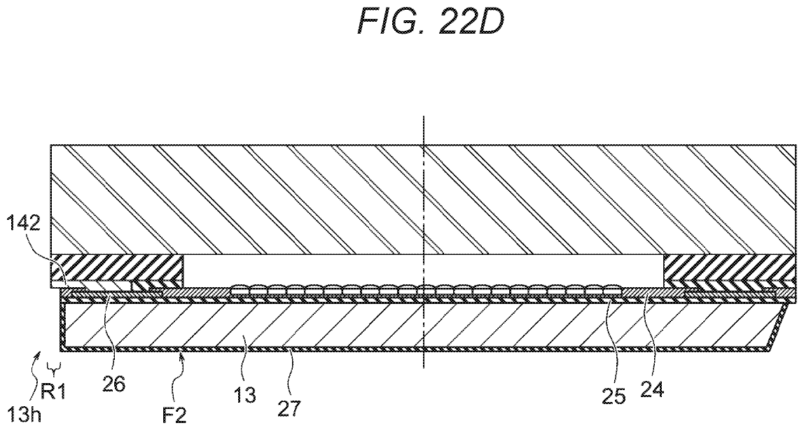

FIGS. 22A to 22D are cross-sectional views illustrating an example of the manufacturing method for the solid-state imaging device 1 according to the third embodiment.

First, as illustrated in FIG. 22A, the imaging element is formed on the front surface F1, and the conductive connection portion 142 is formed. That is, the conductive connection portion 142 electrically connected to the connection pad 26 and extending to the first region R1 including a part of the dividing region for dividing the substrate 13 into individual pieces is formed. The first region R1 is a region where the hole 13h is formed in the substrate 13 in the subsequent process. Note that the size of the first region R1 affects the thickness of the conductor 14 disposed on the side surface F3 when being divided into individual pieces. Thereafter, the protective substrate 18 is attached above the front surface F1 of the substrate 13.

Next, as illustrated in FIG. 22B, the hole 13h is formed in the substrate 13 by etching. The hole 13h is formed in the first region R1 as viewed from the back surface F2 of the substrate 13.

Next, as illustrated in FIG. 22C, the insulating layer 27 is formed on the hole 13h, the back surface F2, and the insulating layer 25 from the back surface F2 side.

Next, as illustrated in FIG. 22D, the organic film 24, and the insulating layers 25 and 27 are etched so as to expose the conductive connection portion 142. That is, the hole 13h extending in the depth direction of the substrate 13 is formed in the first region from the back surface F2 side of the substrate 13 so as to expose the conductive connection portion 142.

Thereafter, the solid-state imaging device 1 illustrated in FIG. 20 is completed by processes similar to those in FIGS. 14E to 14H of the first embodiment. That is, by forming the metal layer 29 from the back surface F2 side of the substrate 13 so as to fill the hole 13h, the conductor 14 electrically connected to the conductive connection portion 142 is formed. Thereafter, the substrate 13 is divided into individual pieces along the dividing region. A part of the metal layer 29 is cut at the time of being divided into individual pieces to form the conductor 14 disposed on the side surface F3.

Furthermore, a sacrificial layer may be used. For example, in FIG. 22A, the sacrificial layer is formed instead of the conductive connection portion 142. Thereafter, the sacrificial layer is removed after the process of FIG. 22D, and the conductive connection portion 142 is formed in a region where the sacrificial layer is removed. At the same time as forming the conductive connection portion 142 or after forming the conductive connection portion 142, by forming the metal layer 29 from the back surface F2 side of the substrate 13 so as to fill the hole 13h, the conductor 14 electrically connected to the conductive connection portion 142 is formed. Thereafter, the substrate 13 is divided into individual pieces along the dividing region.

Note that although not illustrated, as another example of the fourth embodiment, the conductor 14 may be disposed only on a package back surface by patterning the rewiring layer using the resin layer 91.

### Modification Example of Third Embodiment

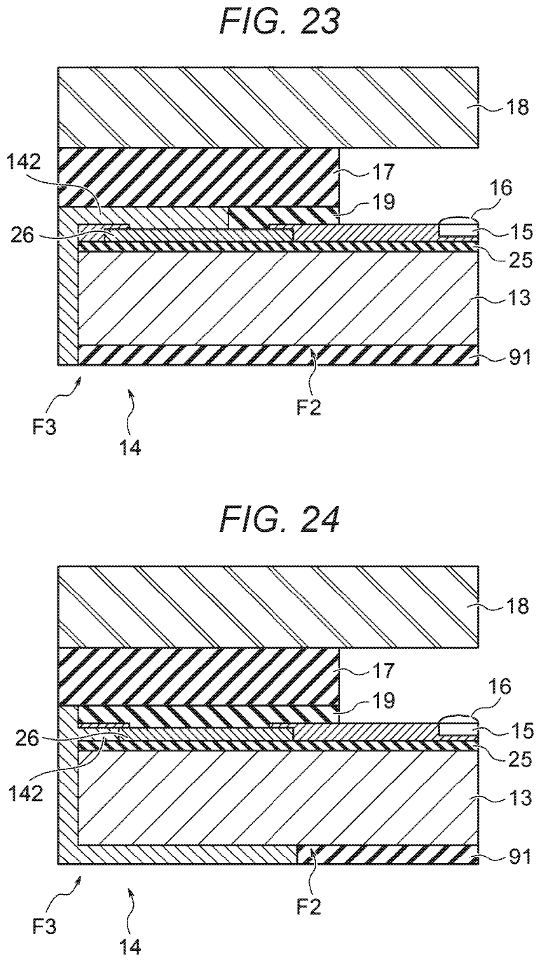

FIG. 23 is an enlarged cross-sectional view illustrating the modification example of a configuration of the solid-state imaging device 1 according to the third embodiment. The modification example of the third embodiment is different from the third embodiment in that the conductor 14 is not provided on the back surface F2.

### Fourth Embodiment

FIG. 24 is an enlarged cross-sectional view illustrating an example of a configuration of the solid-state imaging device 1 according to the fourth embodiment. The fourth embodiment is different from the third embodiment in that the conductor 14 is connected to the side surface of the connection pad 26.

The conductive connection portion 142 is connected to the side surface portion of the connection pad 26. That is, the conductive connection portion 142 is disposed at substantially the same height as the connection pad 26.

A manufacturing method for the solid-state imaging device 1 in the fourth embodiment is substantially similar to that in the third embodiment.

In the fourth embodiment, as in the third embodiment, the connection pad 26 can be electrically connected to the conductor 14 without passing through the inside of the substrate 13 below the conductor 14. Therefore, even in a case where the solid-state imaging device 1 is the stacked sensor, dedicated design of the connection pad 26 becomes unnecessary.

Furthermore, by pulling out the conductive connection portion 142 from the side surface of the connection pad 26 to the scribe area (dividing region) at the time of wafer formation, the processing of the upper surface or lower surface of the connection pad 26 for connection with the conductor 14 disposed on the side surface F3 becomes unnecessary.

Furthermore, in the fourth embodiment, as in the third embodiment, the substrate 13 may be a stacked substrate. Moreover, the connection pad 26 may be disposed on any one of the logic substrate 11 or the pixel sensor substrate 12.

Note that although not illustrated, as another example of the fourth embodiment, the conductor 14 may be disposed only on a package back surface by patterning the rewiring layer using the resin layer 91.

### Modification Example of Fourth Embodiment

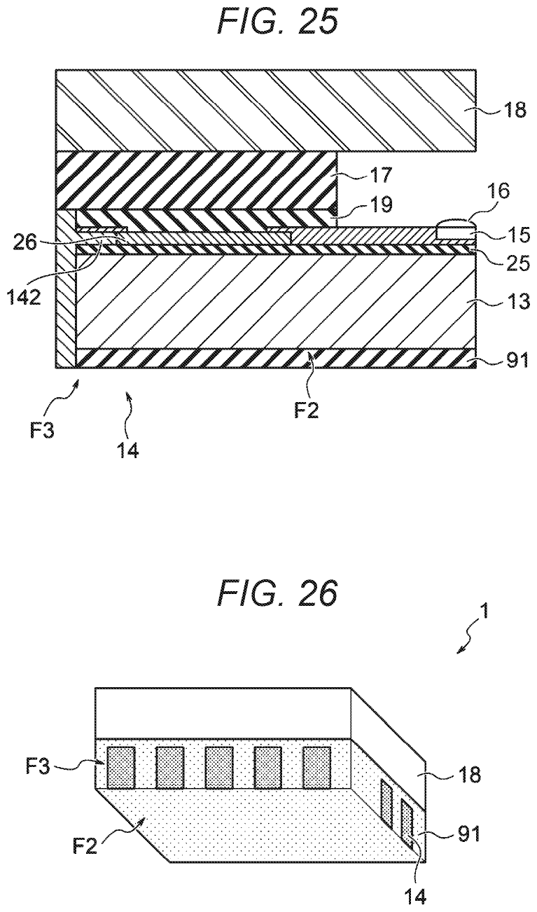

FIG. 25 is an enlarged cross-sectional view illustrating the modification example of a configuration of the solid-state imaging device 1 according to the fourth embodiment. The modification example of the fourth embodiment is different from the fourth embodiment in that the conductor 14 is not provided on the back surface F2.

### Fifth Embodiment

FIG. 26 is a perspective view illustrating a first example of the configuration of the solid-state imaging device 1 according to the fifth embodiment.

In the example illustrated in FIG. 26, the conductor 14 is provided only on the side surface F3. That is, the conductor 14 is not disposed on the back surface F2. A cross section of the conductor 14 in FIG. 26 corresponds to, for example, FIG. 23 and FIG. 25.

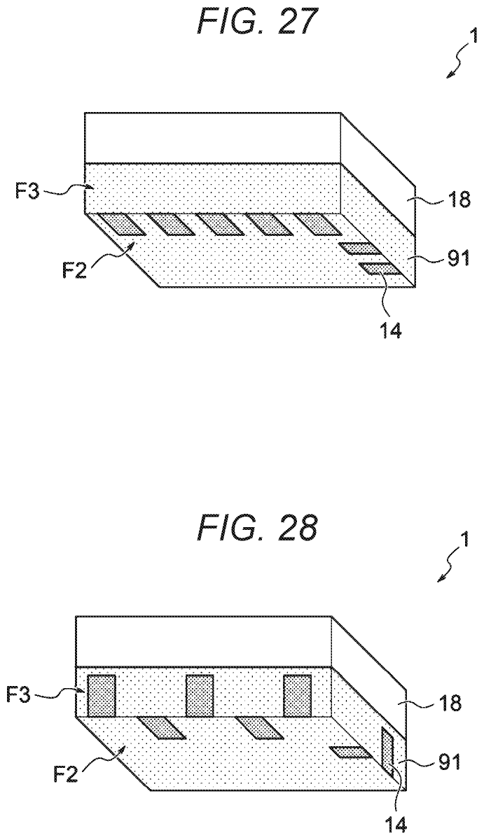

FIG. 27 is a perspective view illustrating a second example of the configuration of the solid-state imaging device 1 according to the fifth embodiment.

In the example illustrated in FIG. 27, the conductor 14 is provided only on the back surface F2. That is, the conductor 14 is not disposed on the side surface F3. A cross section of the conductor 14 in FIG. 27 corresponds to, for example, FIG. 19.

FIG. 28 is a perspective view illustrating a third example of the configuration of the solid-state imaging device 1 according to the fifth embodiment.

The conductor 14 disposed on the back surface F2 and the conductor 14 disposed on the side surface F3 are provided separated from each other. In the example illustrated in FIG. 28, the conductor 14 is disposed only on the back surface F2 or only on the side surface F3 according to the position of the back surface F2 and the position of the side surface F3. More specifically, the conductors 14 may be disposed in a staggered arrangement. That is, the conductors 14 are alternately disposed on the back surface F2 and the side surface F3 along the outer edge of the substrate 13 from the normal direction of the substrate surface of the substrate 13.

As described above, in the fifth embodiment, the conductors 14 are disposed only on the package side surface, only on the package back surface, or on both the package side surface and the package back surface. Therefore, the degree of freedom in designing the connection terminal of the mount substrate 100 can be improved.

### Sixth Embodiment

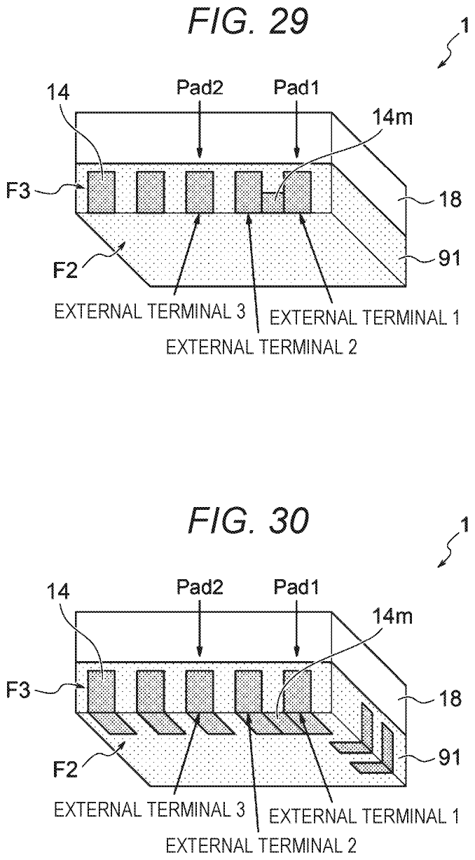

FIG. 29 is a perspective view illustrating a first example of a configuration of the solid-state imaging device 1 according to the sixth embodiment. The first example of the sixth embodiment is different from the first embodiment in that two conductors 14 are electrically connected to each other on the package side surface.

The solid-state imaging device 1 further includes a coupling portion 14m. The coupling portion 14m is disposed on at least one of the back surface F2 or the side surface F3, and couples a plurality of the conductors 14. The coupling portion 14m is formed by, for example, patterning the rewiring layer.

In the example illustrated in FIG. 29, the coupling portion 14m is disposed between two conductors 14 on the side surface F3, and electrically connects two conductors 14 on the package side surface.

In the example illustrated in FIG. 29, the conductor 14 corresponding to and electrically connected to a certain connection pad 26 (Pad 1) is connected to an external terminal 1 of the mount substrate 100. The conductor 14 connected to an external terminal 2 of the mount substrate 100 is not connected to the corresponding connection pad 26. The external terminals 1 and 2 of the mount substrate 100 are electrically connected to the pad 1 by the coupling portion 14m. That is, a plurality of the conductors 14 coupled by the coupling portion 14m shares the connection pad 26 that is electrically connected to the conductors 14 and transmits and receives signals to and from the imaging element.

As described above, in the sixth embodiment, a plurality of the conductors 14 is connected to share one connection pad 26 of the image sensor. Therefore, in a case where a wiring path needs to be separated on the mount substrate 100 side, the package side can cope with this.

Furthermore, the conductor 14 corresponding to and electrically connected to a certain connection pad 26 (Pad 2) is connected to an external terminal 3 of the mount substrate 100. FIG. 30 is a perspective view illustrating a second example of the configuration of the solid-state imaging device 1 according to the sixth embodiment.

In the example illustrated in FIG. 30, the coupling portion 14m is disposed between two conductors 14 on the back surface F2, and electrically connects two conductors 14 on the package back surface.

### Seventh Embodiment

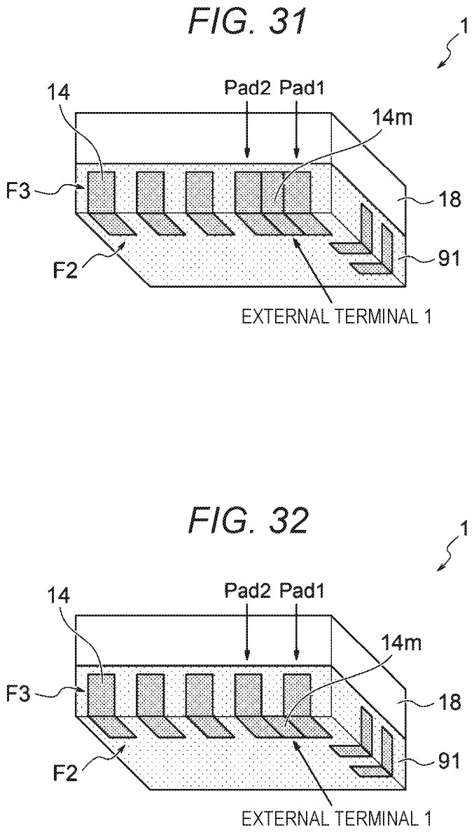

FIG. 31 is a perspective view illustrating a first example of a configuration of the solid-state imaging device 1 according to the seventh embodiment. The first example of the seventh embodiment is different from the sixth embodiment in that one external terminal of the mount substrate 100 is connected to the coupled conductors 14.

In the example illustrated in FIG. 31, the coupling portion 14m is disposed between two conductors 14 on both the back surface F2 and the side surface F3, and electrically connects two conductors 14 on the package back surface and the package side surface.

In the example illustrated in FIG. 31, the coupling portion 14m electrically connects the conductor 14 electrically connected to a certain connection pad 26 (Pad 1) and the conductor 14 electrically connected to another connection pad 26 (Pad 2). That is, a plurality of the conductors 14 coupled by the coupling portion 14m is shared through a plurality of the connection pads 26 that is electrically connected to the conductors 14 and transmits and receives signals to and from the imaging element. A plurality of the coupled conductors 14 is connected to one external terminal of the mount substrate 100.

As described above, in the seventh embodiment, a plurality of the coupled conductors 14 is shared through a plurality of the connection pads 26 of the image sensor. Therefore, in a case where the package terminals need to be coupled (merged) on the mount substrate 100 side, the package side can cope with this.

FIG. 32 is a perspective view illustrating a second example of the configuration of the solid-state imaging device 1 according to the seventh embodiment.

In the example illustrated in FIG. 32, the coupling portion 14m is disposed between two conductors 14 on the back surface F2, and electrically connects two conductors 14 on the package back surface.

### Eighth Embodiment

FIG. 33 is a cross-sectional view illustrating a first example of a configuration of the conductor 14 and substrate 13 according to the eighth embodiment.

The insulating layer 27 is provided between the substrate 13 and the conductor 14.

The conductor 14 is formed by a single layer. That is, the conductor 14 has a single-layered conductive layer. The conductor 14 is formed by, for example, a physical vapor deposition (PVD) method. The conductor 14 is, for example, the metal layer 29. As the material of the conductor 14, a wiring material on the mount substrate 100 side is not limited, and a compatible metal material can be selected in terms of an electrical characteristic and bonding reliability. The material of the single-layered conductor 14 is, for example, Ti, Cu, Ni, Au, SnAg, or Al.

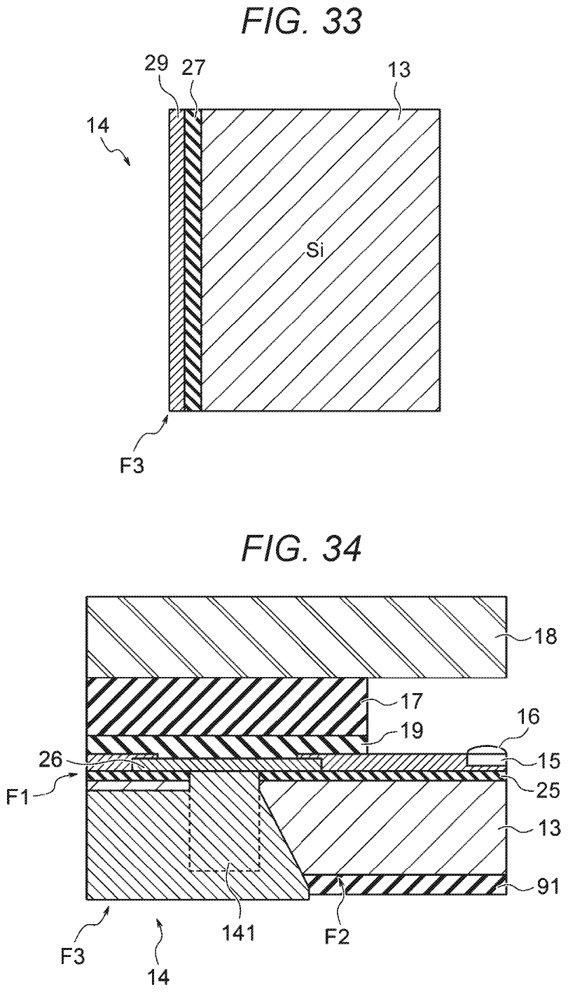

FIG. 34 is an enlarged cross-sectional view illustrating an example of a configuration of the solid-state imaging device 1 according to the eighth embodiment.

In the example illustrated in FIG. 34, a taper is formed on the side surface F3 such that the front surface F1 is wider than the back surface F2. The taper is formed in order to facilitate film formation since it is relatively difficult to cover the step in the PVD method.

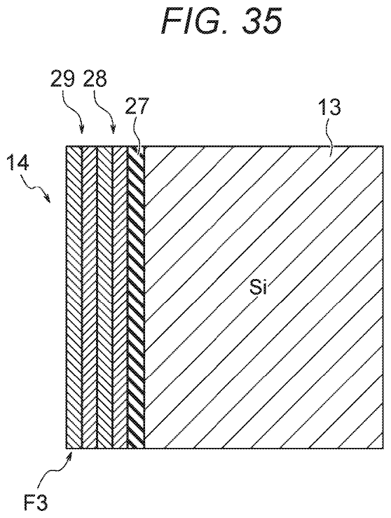

FIG. 35 is a cross-sectional view illustrating a second example of the configuration of the conductor 14 and substrate 13 according to the eighth embodiment.

The conductor 14 is formed by a multilayer. That is, the conductor 14 has a multi-layered conductive layer. The conductor 14 is formed by, for example, plating. The conductor 14 includes, for example, a metal layer 29 (plating layer). For example, the seed layer 28 is disposed between the conductor 14 and the insulating layer 27. The layer configuration is selected, for example, according to the specification of the mount substrate 100. As a plurality of the layers in the conductor 14, for example, a Ti seed layer 28, a Cu seed layer 28, a Ni metal layer 29, and an Au metal layer 29 are disposed from the substrate 13 side. Furthermore, as a plurality of the layers in the conductor 14, for example, a Ti seed layer 28, a Cu seed layer 28, and a SnAg metal layer 29 may be disposed from the substrate 13 side.

Whether to form the conductor 14 with a single layer or a multilayer in the sixth embodiment is changed depending on, for example, design, use, or the like. For example, in a case where the film thickness of the conductor 14 is increased, it is preferable to form the seed layer 28 and form the conductor 14 by electrolytic plating rather than the PVD method from the viewpoint of mass production, a film forming speed, and the like. For example, in a case where the film thickness is several tens nm to several hundreds nm, the conductor 14 may be formed by the PVD method. However, when the film thickness is equal to or greater than several μm, the electroplating is lower in cost.

Furthermore, from the viewpoint of reliability, the conductor 14 is preferably formed by a multilayer. Solder 110 leaches into the metal in the conductor 14, which may lead to, for example, peeling-off of the conductor 14. In a case where the conductor 14 is formed by the multilayer, in the conductor 14, the multilayer is more reliable than the single layer since there are a plurality of the layers on the outer side.

### <Application Example to Mobile Body>

The technology according to the present disclosure (the present technology) can be applied to various products. For example, the technology according to the present disclosure may be realized as a device mounted on any type of mobile bodies, such as an automobile, an electric vehicle, a hybrid electric vehicle, a motorcycle, a bicycle, personal mobility, an airplane, a drone, a ship, a robot, and the like.

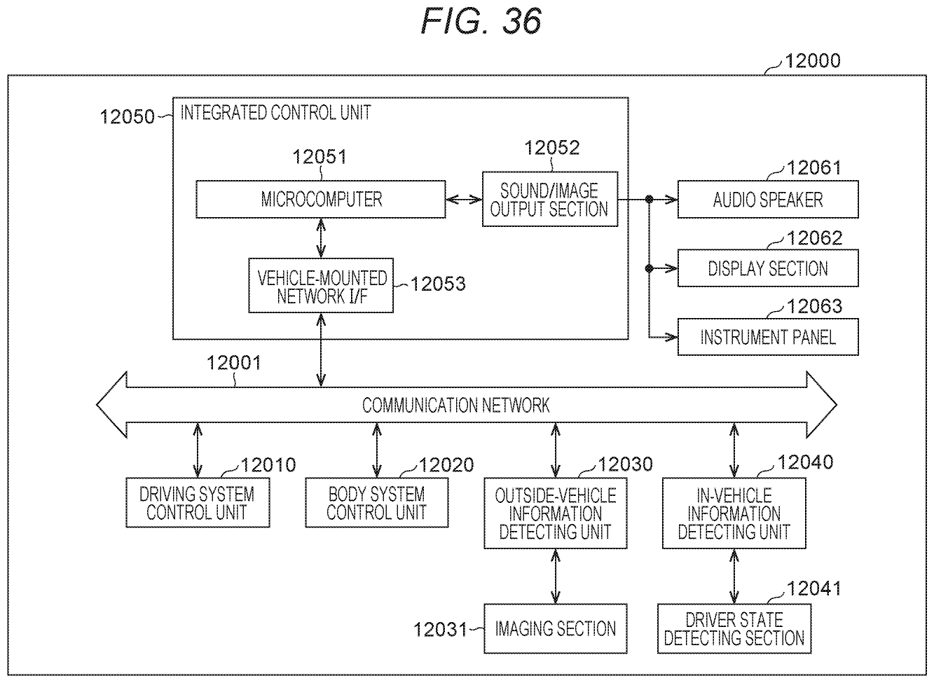

FIG. 36 is a block diagram illustrating a schematic configuration example of a vehicle control system as an example of a mobile body control system to which the technology according to the present disclosure is applied.

A vehicle control system 12000 includes a plurality of electronic control units connected to each other via a communication network 12001. In the example illustrated in FIG. 36, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle, which is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 36, an audio speaker 12061, a display section 12062, and an instrument panel 12063 are illustrated as the output device. The display section 12062 may, for example, include at least one of an on-board display and a head-up display.

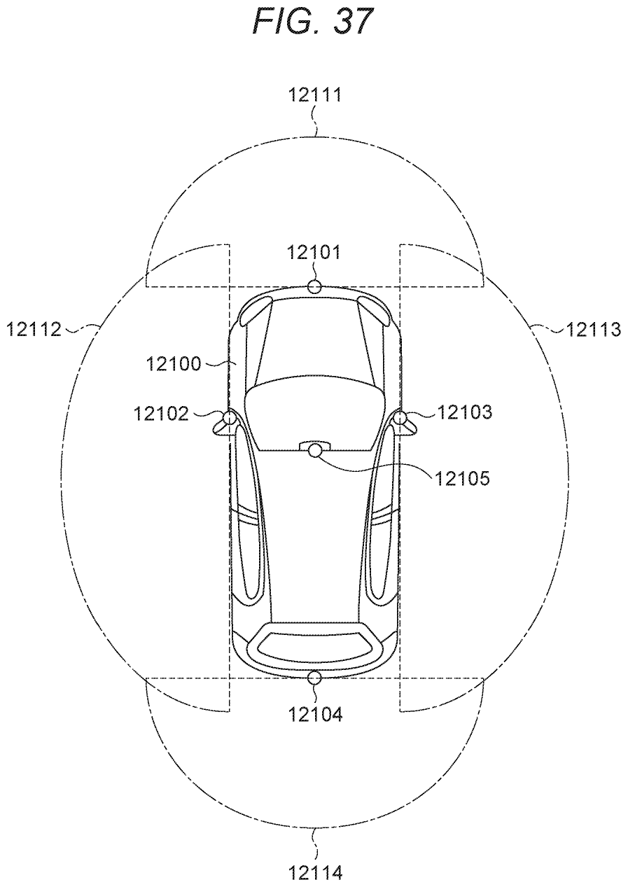

FIG. 37 is a view illustrating an example of an installation position of the imaging section 12031.

In FIG. 37, a vehicle 12100 includes imaging sections 12101, 12102, 12103, 12104, and 12105, as the imaging section 12031.

The imaging sections 12101, 12102, 12103, 12104, and 12105 are, for example, provided at positions on a front nose, sideview mirrors, a rear bumper, and a back door of the vehicle 12100 as well as a position on an upper portion of a windshield in the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided on the sideview mirrors mainly obtain images of the sideward sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that FIG. 37 illustrates an example of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure can be applied has been described above. The technology according to the present disclosure can be applied to, for example, the imaging sections 12031, 12101, 12102, 12103, 12104, and 12105, the driver state detecting section 12041, and the like among the above-described configurations. Specifically, for example, the solid-state imaging device 1 of the present disclosure can be applied to these imaging sections and detecting section. Then, by applying the technology according to the present disclosure, the package size can be further reduced, and thus the size of the system can be reduced.

Note that the present technology can have the following configurations.

(1) A solid-state imaging device including:
a substrate including an imaging element configured to generate an electric signal obtained by photoelectrically converting light incident on a first surface; and
a conductor disposed on at least one of a second surface opposite to the first surface of the substrate or a side surface continuous with the second surface of the substrate and electrically connected to the imaging element.

(2) The solid-state imaging device according to (1), in which the conductor is in surface contact with at least one of the second surface or the side surface.

(3) The solid-state imaging device according to (1) or (2), in which on at least one of the second surface or the side surface, an arrangement place of the conductor is flush with other places.

(4) The solid-state imaging device according to any one of (1) to (3), further including a contact member extending in a depth direction of the substrate and electrically connected to the imaging element,
in which the conductor is electrically connected to the contact member.

(5) The solid-state imaging device according to (4), in which the substrate includes a signal output unit configured to transmit and receive a signal to and from the imaging element, and
the signal output unit is connected to one end of the contact member.

(6) The solid-state imaging device according to (4) or (5), in which the substrate includes:
a first substrate on which a photoelectric conversion unit in the imaging element is disposed; and
a second substrate that is stacked on the first substrate and performs signal processing on an electric signal photoelectrically converted by the photoelectric conversion unit, and
the contact member extends in the depth direction of the first substrate and second substrate.

(7) The solid-state imaging device according to any one of (1) to (3), in which the substrate includes:
a first substrate on which a photoelectric conversion unit in the imaging element is disposed; and
a second substrate that is stacked on the first substrate and performs signal processing on an electric signal photoelectrically converted by the photoelectric conversion unit,
the first substrate includes a signal output unit configured to transmit and receive a signal to and from the imaging element,
the first substrate includes a conductive connection portion electrically connected to the signal output unit and extending to a side surface of the first substrate, and
the conductor is connected to the conductive connection portion and disposed on the side surface of the first substrate.

(8) The solid-state imaging device according to any one of (1) to (3), in which the substrate includes:
a first substrate on which a photoelectric conversion unit in the imaging element is disposed; and
a second substrate that is stacked on the first substrate and performs signal processing on an electric signal photoelectrically converted by the photoelectric conversion unit,
the second substrate includes a signal output unit configured to transmit and receive a signal to and from the imaging element,
the second substrate includes a conductive connection portion electrically connected to the signal output unit and extending to a side surface of the second substrate, and
the conductor is connected to the conductive connection portion and disposed on the side surface of the second substrate.

(9) The solid-state imaging device according to any one of (6) to (8), in which the conductor is disposed on side surfaces of the first substrate and second substrate and on the second surface of the second substrate.

(10) The solid-state imaging device according to any one of (1) to (9), in which the conductor is disposed only on the second surface or only on the side surface.

(11) The solid-state imaging device according to any one of (1) to (9), in which the conductor is disposed continuously from the second surface to the side surface.

(12) The solid-state imaging device according to any one of (1) to (9), in which the conductor disposed on the second surface and the conductor disposed on the side surface are provided separated from each other.

(13) The solid-state imaging device according to any one of (1) to (12), further including a coupling portion that is disposed on at least one of the second surface or the side surface, and couples a plurality of the conductors,
in which a plurality of the conductors coupled by the coupling portion shares a signal output unit electrically connected to the conductors and configured to transmit and receive a signal to and from the imaging element.

(14) The solid-state imaging device according to any one of (1) to (12), further including a coupling portion that is disposed on at least one of the second surface or the side surface, and couples a plurality of the conductors,
in which a plurality of the conductors coupled by the coupling portion is shared through a plurality of signal output units electrically connected to the conductors and configured to transmit and receive a signal to and from the imaging element.

(15) The solid-state imaging device according to any one of (1) to (14), in which the conductor includes a single-layered conductive layer.

(16) The solid-state imaging device according to any one of (1) to (14), in which the conductor includes a plurality of stacked conductive layers.

(17) A manufacturing method for a solid-state imaging device, the method including:
forming, on a first surface of a substrate, an imaging element configured to generate an electric signal obtained by photoelectrically converting light incident on the first surface; and
forming a conductor disposed on at least one of a second surface opposite to the first surface of the substrate or a side surface continuous with the second surface of the substrate and electrically connected to the imaging element.

(18) The manufacturing method for a solid-state imaging device according to (17), further including:
forming the imaging element on the first surface of the substrate;
forming a hole extending in a depth direction of the substrate from the second surface side of the substrate so as to expose a signal output unit configured to transmit and receive a signal to and from the imaging element; and
forming a contact member extending in the depth direction of the substrate and the conductor electrically connected to the contact member by forming a metal layer from the second surface side of the substrate so as to fill the hole.

(19) The manufacturing method for a solid-state imaging device according to (17), further including:
forming the imaging element on the first surface of the substrate before dividing the substrate into individual pieces;
forming a conductive connection portion electrically connected to a signal output unit configured to transmit and receive a signal to and from the imaging element and extending to a first region including a part of a dividing region for dividing the substrate into individual pieces;
forming, in the first region, a hole extending in a depth direction of the substrate from the second surface side of the substrate such that the conductive connection portion is exposed;
forming a metal layer from the second surface side of the substrate so as to fill the hole to form the conductor electrically connected to the conductive connection portion; and
dividing the substrate into individual pieces along the dividing region.

(20) The manufacturing method for a solid-state imaging device according to (17), further including:
forming the imaging element on the first surface of the substrate before dividing the substrate into individual pieces;
forming a sacrificial layer extending to a first region including a part of a dividing region for dividing the substrate into individual pieces;
forming, in the first region, a hole extending in a depth direction of the substrate from the second surface side of the substrate such that the sacrificial layer is exposed;
removing the sacrificial layer;
forming, in a region where the sacrificial layer is removed, a conductive connection portion electrically connected to a signal output unit configured to transmit and receive a signal to and from the imaging element and forming a metal layer from the second surface side of the substrate so as to fill the hole to form the conductor electrically connected to the conductive connection portion; and
dividing the substrate into individual pieces along the dividing region.

Aspects of the present disclosure are not limited to the above-described individual embodiments, and include various modifications that may be conceived by those skilled in the art, and the effects of the present disclosure are not limited to the above-described content. That is, various additions, modifications, and partial deletions are possible without departing from the conceptual idea and spirit of the present disclosure derived from the matters defined in the claims and equivalents thereof.

### REFERENCE SIGNS LIST

1 Solid-state imaging device
11 Lower-side substrate
12 Upper-side substrate
13 Substrate
13h Hole
14 Conductor
141 Contact member
142 Conductive connection portion
14m Coupling portion
18 Protective substrate
26 Connection pad
29 Metal layer
F1 Front surface
F2 Back surface
F3 Side surface
R1 First region
R2 Second region

1. A solid-state imaging device comprising:
a substrate including an imaging element configured to generate an electric signal obtained by photoelectrically converting light incident on a first surface; and
a conductor disposed on at least one of a second surface opposite to the first surface of the substrate or a side surface continuous with the second surface of the substrate and electrically connected to the imaging element.

2. The solid-state imaging device according to claim 1, wherein the conductor is in surface contact with at least one of the second surface or the side surface.

3. The solid-state imaging device according to claim 1, wherein on at least one of the second surface or the side surface, an arrangement place of the conductor is flush with other places.

4. The solid-state imaging device according to claim 1, further comprising a contact member extending in a depth direction of the substrate and electrically connected to the imaging element,
wherein the conductor is electrically connected to the contact member.

5. The solid-state imaging device according to claim 4, wherein the substrate includes a signal output unit configured to transmit and receive a signal to and from the imaging element, and
the signal output unit is connected to one end of the contact member.

6. The solid-state imaging device according to claim 4, wherein the substrate includes:
a first substrate on which a photoelectric conversion unit in the imaging element is disposed; and
a second substrate that is stacked on the first substrate and performs signal processing on an electric signal photoelectrically converted by the photoelectric conversion unit, and
the contact member extends in the depth direction of the first substrate and second substrate.

7. The solid-state imaging device according to claim 1, wherein the substrate includes:
a first substrate on which a photoelectric conversion unit in the imaging element is disposed; and
a second substrate that is stacked on the first substrate and performs signal processing on an electric signal photoelectrically converted by the photoelectric conversion unit,
the first substrate includes a signal output unit configured to transmit and receive a signal to and from the imaging element,
the first substrate includes a conductive connection portion electrically connected to the signal output unit and extending to a side surface of the first substrate, and
the conductor is connected to the conductive connection portion and disposed on the side surface of the first substrate.

8. The solid-state imaging device according to claim 1, wherein the substrate includes:
a first substrate on which a photoelectric conversion unit in the imaging element is disposed; and
a second substrate that is stacked on the first substrate and performs signal processing on an electric signal photoelectrically converted by the photoelectric conversion unit,
the second substrate includes a signal output unit configured to transmit and receive a signal to and from the imaging element,
the second substrate includes a conductive connection portion electrically connected to the signal output unit and extending to a side surface of the second substrate, and
the conductor is connected to the conductive connection portion and disposed on the side surface of the second substrate.

9. The solid-state imaging device according to claim 6, wherein the conductor is disposed on side surfaces of the first substrate and second substrate and on the second surface of the second substrate.

10. The solid-state imaging device according to claim 1, wherein the conductor is disposed only on the second surface or only on the side surface.

11. The solid-state imaging device according to claim 1, wherein the conductor is disposed continuously from the second surface to the side surface.

12. The solid-state imaging device according to claim 1, wherein the conductor disposed on the second surface and the conductor disposed on the side surface are provided separated from each other.

13. The solid-state imaging device according to claim 1, further comprising a coupling portion that is disposed on at least one of the second surface or the side surface, and couples a plurality of the conductors,
wherein a plurality of the conductors coupled by the coupling portion shares a signal output unit electrically connected to the conductors and configured to transmit and receive a signal to and from the imaging element.

14. The solid-state imaging device according to claim 1, further comprising a coupling portion that is disposed on at least one of the second surface or the side surface, and couples a plurality of the conductors,
wherein a plurality of the conductors coupled by the coupling portion is shared through a plurality of signal output units electrically connected to the conductors and configured to transmit and receive a signal to and from the imaging element.

15. The solid-state imaging device according to claim 1, wherein the conductor includes a single-layered conductive layer.

16. The solid-state imaging device according to claim 1, wherein the conductor includes a plurality of stacked conductive layers.

17. A manufacturing method for a solid-state imaging device, the method comprising:
forming, on a first surface of a substrate, an imaging element configured to generate an electric signal obtained by photoelectrically converting light incident on the first surface; and
forming a conductor disposed on at least one of a second surface opposite to the first surface of the substrate or a side surface continuous with the second surface of the substrate and electrically connected to the imaging element.

18. The manufacturing method for a solid-state imaging device according to claim 17, further comprising:
forming the imaging element on the first surface of the substrate;
forming a hole extending in a depth direction of the substrate from the second surface side of the substrate so as to expose a signal output unit configured to transmit and receive a signal to and from the imaging element; and
forming a contact member extending in the depth direction of the substrate and the conductor electrically connected to the contact member by forming a metal layer from the second surface side of the substrate so as to fill the hole.

19. The manufacturing method for a solid-state imaging device according to claim 17, further comprising:
forming the imaging element on the first surface of the substrate before dividing the substrate into individual pieces;
forming a conductive connection portion electrically connected to a signal output unit configured to transmit and receive a signal to and from the imaging element and extending to a first region including a part of a dividing region for dividing the substrate into individual pieces;
forming, in the first region, a hole extending in a depth direction of the substrate from the second surface side of the substrate such that the conductive connection portion is exposed;
forming a metal layer from the second surface side of the substrate so as to fill the hole to form the conductor electrically connected to the conductive connection portion; and
dividing the substrate into individual pieces along the dividing region.

20. The manufacturing method for a solid-state imaging device according to claim 17, further comprising:
forming the imaging element on the first surface of the substrate before dividing the substrate into individual pieces;
forming a sacrificial layer extending to a first region including a part of a dividing region for dividing the substrate into individual pieces;
forming, in the first region, a hole extending in a depth direction of the substrate from the second surface side of the substrate such that the sacrificial layer is exposed;
removing the sacrificial layer;
forming, in a region where the sacrificial layer is removed, a conductive connection portion electrically connected to a signal output unit configured to transmit and receive a signal to and from the imaging element and forming a metal layer from the second surface side of the substrate so as to fill the hole to form the conductor electrically connected to the conductive connection portion; and
dividing the substrate into individual pieces along the dividing region.
